(19) United States
(12) Patent Application Publication
(10) Pub. No.: US 2026/0025999 A1
(43) Pub. Date: Jan. 22, 2026

(54) SEMICONDUCTOR STRUCTURE, MANUFACTURING METHOD THEREOF AND MEMORY SYSTEM

(71) Applicant: Yangtze Memory Technologies Co., Ltd., Wuhan (CN)

(72) Inventors: Tingting ZHAO, Wuhan (CN); Zongliang HUO, Wuhan (CN); Jing GAO, Wuhan (CN); Sizhe LI, Wuhan (CN); Wenbo ZHANG, Wuhan (CN); Zengpeng ZHANG, Wuhan (CN)

(21) Appl. No.: 19/223,770

(22) Filed: May 30, 2025

(30) Foreign Application Priority Data
Jul. 16, 2024 (CN) 202410955646.9

(51) Int. Cl. H10B 43/27

(52) U.S. Cl. CPC H10B 43/27

(57) ABSTRACT

Semiconductor structures, manufacturing methods thereof, and memory systems are provided. An example semiconductor structure includes a first stack structure, a second stack structure, a semiconductor layer, a first staircase structure, a second staircase structure, and a connection structure. The second stack structure is on a side of the first stack structure. The semiconductor layer is between the first stack structure and the second stack structure. The first staircase structure is in the first stack structure and includes a plurality of first step structures arranged along a first circumferential direction. The second staircase structure is in the second stack structure and includes a plurality of second step structures arranged along a second circumferential direction. The connection structure extends along a stacking direction of the first stack structure and the second stack structure and is connected with a first step structure and a second step structure.

### CROSS-REFERENCE TO RELATED APPLICATIONS

This application claims the benefit of priority to Chinese Patent Application No. 202410955646.9, filed on Jul. 16, 2024, the disclosure of which is hereby incorporated by reference in its entirety.

### TECHNICAL FIELD

The present disclosure relates to the field of semiconductor technology, and more particularly, to a semiconductor structure, a memory system, and a manufacturing method of a semiconductor structure.

### BACKGROUND

In order to improve the integration level of the semiconductor structure, the number of stack layers in the semiconductor structure continues to increase. However, a higher number of stack layers results in an increase in the planar dimension of the semiconductor structure and also increases the manufacturing difficulty and cost of the semiconductor structure.

### SUMMARY

In a first aspect, examples of the present disclosure provide a semiconductor structure. The semiconductor structure comprises a first stack structure, a second stack structure, a semiconductor layer, a first staircase structure, a second staircase structure and a connection structure. The second stack structure is located on a side of the first stack structure. The semiconductor layer is located between the first stack structure and the second stack structure. The first staircase structure is located in the first stack structure and comprises a plurality of first step structures arranged along a circumferential direction. The second staircase structure is located in the second stack structure and comprises a plurality of second step structures arranged along the circumferential direction. The connection structure extends along a stacking direction of the first stack structure and the second stack structure and is connected with one of the first step structures and one of the second step structures.

In an implementation, the first step structure comprises a plurality of first step sub-structures arranged along a radial direction, and the second step structure comprises a plurality of second step sub-structures arranged along a radial direction, wherein the connection structure is connected with one of the first step sub-structures and one of the second step sub-structures.

In an implementation, with respect to the semiconductor layer, the depths of the plurality of first step sub-structures are different from each other, and the depths of the plurality of second step sub-structures are different from each other.

In an implementation, in a plane perpendicular to the stacking direction, the first staircase structure comprises a plurality of first step regions arranged along the circumferential direction, the first step structure is located in adjacent first step regions, the second staircase structure comprises a plurality of second step regions arranged along the circumferential direction, and the second step structure is located in adjacent second step regions, wherein a shape of the first step region comprises a sector, and a shape of the second step region comprises a sector.

In an implementation, the first staircase structure and the second staircase structure are at least partially aligned in a stacking direction.

In an implementation, the semiconductor structure further comprises a first insulating structure and a second insulating structure. The first insulating structure is located on a side of the first staircase structure close to the semiconductor layer, and the second insulating structure is located on a side of the second staircase structure away from the semiconductor layer. The connection structure comprises a first connecting portion and a second connecting portion. The first connecting portion extends through the first insulating structure and extends to the first staircase structure. The second connecting portion extends through the second insulating structure and extends to the second staircase structure.

In an implementation, the semiconductor structure further comprises a first insulating structure and a second insulating structure. The first insulating structure is located on a side of the first staircase structure close to the semiconductor layer, and the second insulating structure is located on a side of the second staircase structure away from the semiconductor layer. The connection structure extends through the second insulating structure, the second staircase structure, the first insulating structure and the first staircase structure.

In an implementation, the semiconductor structure further comprises an isolation layer surrounding a portion of the connection structure extending through the first staircase structure and the second staircase structure.

In an implementation, in a plane perpendicular to the stacking direction, a dimension of a portion of the connection structure extending through the first insulating structure is greater than a dimension of a portion of the connection structure extending through the first staircase structure; and in a plane perpendicular to the stacking direction, a dimension of a portion of the connection structure extending through the second insulating structure is greater than a dimension of a portion of the connection structure extending through the second staircase structure.

In an implementation, the semiconductor structure further comprises a first surrounding portion and a second surrounding portion. The first surrounding portion surrounds the connection structure and is in contact with the first staircase structure. The second surrounding portion surrounds the connection structure and is in contact with the second staircase structure.

In an implementation, the first stack structure comprises a first stack portion and a second stack portion arranged along a stacking direction, the first staircase structure is located in the first stack portion, the second stack portion covers the first insulating structure, the connection structure extends through the second stack portion, and the isolation layer surrounds a portion of the connection structure extending through the second stack portion.

In an implementation, the semiconductor structure further comprises a first insulating layer and a second insulating layer. The first insulating layer is located between the first staircase structure and the first insulating structure, and the second insulating layer is located between the second staircase structure and the second insulating structure.

In an implementation, the connection structure comprises a plurality of connection sub-structures arranged along the stacking direction, and a dimension of the connection sub-structure in a plane perpendicular to the stacking direction increases gradually along the stacking direction.

In an implementation, the semiconductor structure further comprises a first bit line structure and a second bit line structure. The first bit line structure is located on a side of the first stack structure away from the semiconductor layer and extends in the first direction, and the second bit line structure is located on a side of the second stack structure away from the semiconductor layer and extends in the first direction. The first direction intersects with the stacking direction.

In an implementation, the semiconductor structure further comprises a first channel structure. The first channel structure extends through the second stack structure, the semiconductor layer, and the first stack structure and is connected with the first bit line structure and the second bit line structure.

In an implementation, the semiconductor structure further comprises a second channel structure. The second channel structure extends through the second staircase structure and the first staircase structure.

In an implementation, the first staircase structure comprises first dielectric layers and first gate layers arranged alternately in the stacking direction, and the second staircase structure comprises second dielectric layers and second gate layers arranged alternately in the stacking direction, wherein the connection structure is connected with one of the first gate layers in the first step sub-structure, and is connected with one of the second gate layers in the second step sub-structure.

In an implementation, a top layer of the first step sub-structure is a first gate layer, and the first gate layers of top layers of the plurality of first step sub-structures are different from each other; a top layer of the second step sub-structure is a second gate layer, and the second gate layers of top layers of the plurality of second step sub-structures are different from each other.

In an implementation, the first staircase structure comprises a plurality of first staircase structures, and the first gate layers of top layers of the plurality of first step sub-structures in each of the first staircase structures are different from each other; the second staircase structure comprises a plurality of second staircase structures, and the second gate layers of top layers of the plurality of second step sub-structures in each of the second staircase structures are different from each other.

In an implementation, the first stack structure comprises first dielectric layers and first gate layers arranged alternately in the stacking direction, and the second stack structure comprises second dielectric layers and second gate layers arranged alternately in the stacking direction.

In a second aspect, examples of the present disclosure provide a memory system. The memory system comprises a memory and a controller. The memory comprises the semiconductor structure mentioned in any of the implementations above. The controller is coupled with the memory and configured to control the memory to store data.

In a third aspect, examples of the present disclosure provide a manufacturing method of a semiconductor structure. The manufacturing method of the semiconductor structure comprises: forming a first staircase structure in a first stack structure, wherein the first staircase structure comprises a plurality of first step structures arranged along the circumferential direction; forming a semiconductor layer on a side of the first stack structure; forming a second stack structure on a side of the semiconductor layer away from the first stack structure, and forming a second staircase structure in the second stack structure, wherein the second staircase structure comprises a plurality of second step structures arranged along the circumferential direction; and forming a connection structure extending along the stacking direction of the first stack structure and the second stack structure, wherein the connection structure is connected with one of the first step structures and one of the second step structures.

In an implementation, the manufacturing method further comprises: forming a first insulating structure on a side of the first staircase structure close to the semiconductor layer; and forming a second insulating structure on a side of the second staircase structure away from the semiconductor layer.

In an implementation, forming the connection structure extending along the stacking direction of the first stack structure and the second stack structure comprises: forming a connection hole extending through the second insulating structure, the second staircase structure, the first insulating structure and the first staircase structure; forming an isolation layer on a sidewall of a portion of the first staircase structure and the second staircase structure through which the connection hole extends; and forming the connection structure in the connection hole where the isolation layer is formed.

In an implementation, the first staircase structure comprises first dielectric layers and first gate layers arranged alternately in the stacking direction, and the second staircase structure comprises second dielectric layers and second gate layers arranged alternately in the stacking direction.

In an implementation, the manufacturing method further comprises: removing a portion of the second insulating structure, the second dielectric layer, the first insulating structure, and the first dielectric layer at periphery of the connection hole; wherein forming the isolation layer on a sidewall of a portion of the first staircase structure and the second staircase structure through which the connection hole extends comprises: forming an initial isolation layer on a sidewall of the connection hole; and removing a portion of the initial isolation layer at a surface of the first gate layer in the first staircase structure, and a portion of the initial isolation layer at a surface of the second gate layer in the second staircase structure, wherein a remainder of the initial isolation layer serves as the isolation layer.

In an implementation, the manufacturing method further comprises: forming a first insulating layer between the first staircase structure and the first insulating structure, wherein the first insulating layer is in contact with the first gate layer; forming a second insulating layer between the second staircase structure and the second insulating structure, wherein the second insulating layer is in contact with the second gate layer, and the connection hole extends through the first insulating layer and the second insulating layer; removing a portion of the first insulating layer and the second insulating layer at periphery of the connection hole to form an annular groove communicating with the connection hole; and filling a conductive material in the annular groove.

In an implementation, the manufacturing method further comprises: forming a first bit line structure on a side of the first stack structure away from the semiconductor layer; and forming a second bit line structure on a side of the second stack structure away from the semiconductor layer; wherein the first bit line structure and the second bit line structure extend in a first direction, and the first direction intersects with the stacking direction.

In an implementation, the manufacturing method further comprises: forming a first channel structure extending through the second stack structure, the semiconductor layer and the first stack structure, wherein the first channel structure is connected with the first bit line structure and the second bit line structure.

### BRIEF DESCRIPTION OF THE DRAWINGS

Other features, objectives and advantages of the present disclosure will become more apparent upon reading the detailed description of non-limiting examples made with reference to the following drawings.

FIG. 1A is a cross-sectional view of a semiconductor structure according to an example of the present disclosure;

FIG. 1B is a top view of a semiconductor structure according to an example of the present disclosure;

FIG. 1C is a perceptive view of a first staircase structure in a semiconductor structure according to an example of the present disclosure;

FIG. 1D is a partial enlarged view of a semiconductor structure according to an example of this disclosure;

FIG. 1E is a cross-sectional view of a semiconductor structure taken in another plane according to an example of the present disclosure;

FIG. 1F is a circuit diagram of a semiconductor structure according to an example of the present disclosure;

FIG. 2A to FIG. 2E are top views of a first staircase structure according to an example of the present disclosure;

FIG. 3 is a cross-sectional view of a semiconductor structure according to another example of the present disclosure;

FIG. 4 is a cross-sectional view of a semiconductor structure according to another example of the present disclosure;

FIG. 5 is a process diagram of a manufacturing method of a semiconductor structure according to an example of the present disclosure;

FIG. 6A to FIG. 6G are cross-sectional views of a semiconductor structure in a manufacturing process according to an example of the present disclosure;

FIG. 7A to FIG. 7F are cross-sectional views of a semiconductor structure in a manufacturing process according to another example of the present disclosure;

FIG. 8 is a schematic block diagram of a system with a memory system according to an example of this disclosure; and

FIG. 9A and FIG. 9B are schematic block diagrams of a memory system according to an example of this disclosure.

### DETAILED DESCRIPTION

In order to have a better understanding of the present disclosure, various aspects of the present disclosure will be described in more detail with reference to the accompanying drawings. It should be understood that these detailed descriptions are merely descriptions of implementations of the present disclosure, and are not intended to limit the scope of the present disclosure in any way. Throughout the specification, like reference numbers refer to like elements. The expression “and/or” comprises any and all combinations of one or more of the associated listed items.

It should be noted that in this specification, the expressions of the first, second, third, etc. are merely used to distinguish one feature from another feature, and do not represent any limitation on the feature, and in particular, do not represent any order. Thus, the first stack structure discussed herein may also be referred to as a second stack structure, the first bit line structure may also be referred to as a second bit line structure, and vice versa, without departing from the teachings of the present disclosure.

In the drawings, the thickness, dimension, and shape of the components have been slightly adjusted for ease of illustration. The drawings are merely examples and are not drawn to scale. As used herein, the terms “approximate,” “about,” and the like are used as the terms for approximation, and are not used as terms for degree, and are intended to illustrate inherent deviations in measured values or calculated values to be recognized by one of ordinary skill in the art.

It should also be understood that expressions such as “comprise”, “comprising”, “having”, “include”, and/or “including”, and the like, are open and not closed expressions in this specification that indicate the presence of stated features, elements, and/or components, but do not preclude the presence of one or more other features, elements, components, and/or combinations thereof. Furthermore, when an expression such as “at least one of” appear after the list of listed features, it refers to the entire list of features rather than just referring to an individual clement in the list. Furthermore, when describing implementations of the present disclosure, the term “may” refers to “one or more implementations of the present disclosure”. Also, the term “example” is intended to refer to an example or illustration.

Unless otherwise defined, all terms (comprising engineering terms and scientific terms) used herein have the same meaning as those of ordinary skill in the art to which this disclosure pertains. It should also be understood that unless stated explicitly in the present disclosure, words defined in commonly used dictionaries should be interpreted as having a meaning that is consistent with their meaning in the context of the related art, and should not be interpreted in an idealized or overly formal sense.

It should be noted that, in the case of no conflict, implementations and features in the implementations of the present disclosure may be combined with each other. In addition, unless expressly defined or contradicted with context, the specific steps comprised in the methods described in this disclosure are not necessarily limited to the recited order, but may be performed in any order or in parallel.

Furthermore, direct or indirect contact between the respective components may be represented in the present disclosure when “connected” or “coupled” is used, unless otherwise defined or otherwise derivable from the context.

The present disclosure will be described below in detail with reference to the accompanying drawings in combination with the examples.

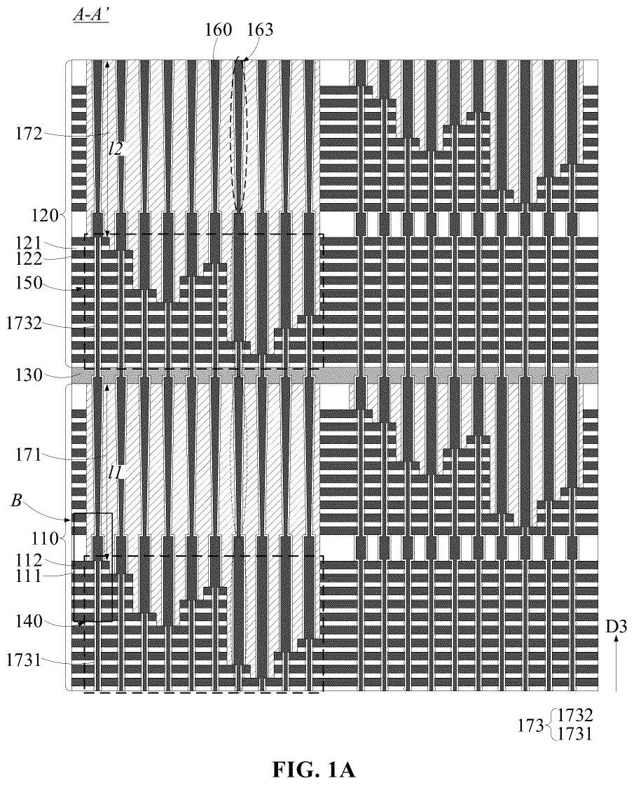

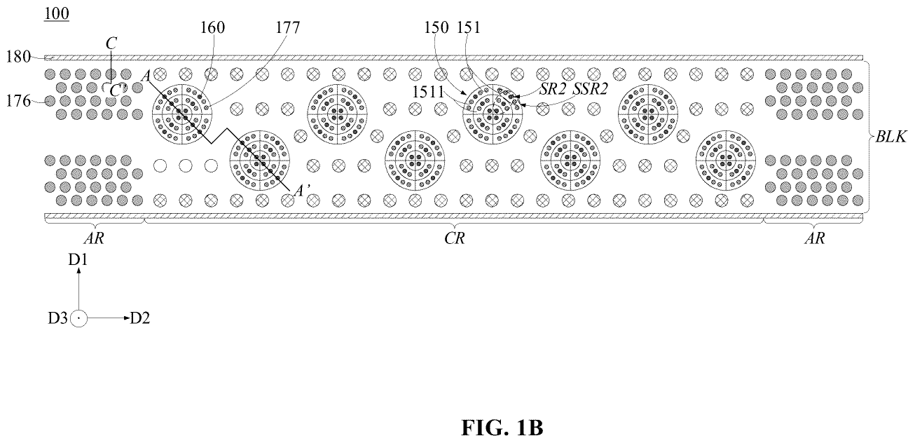

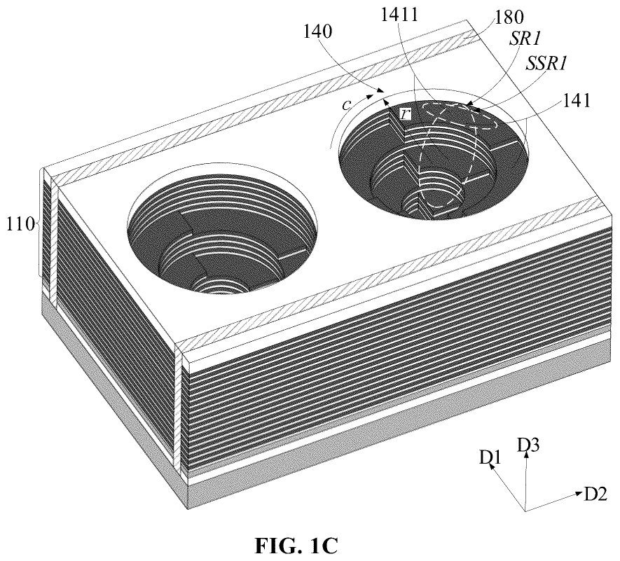

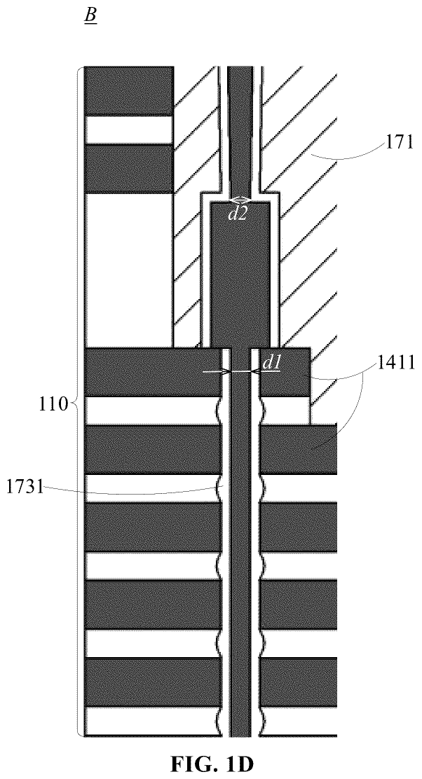

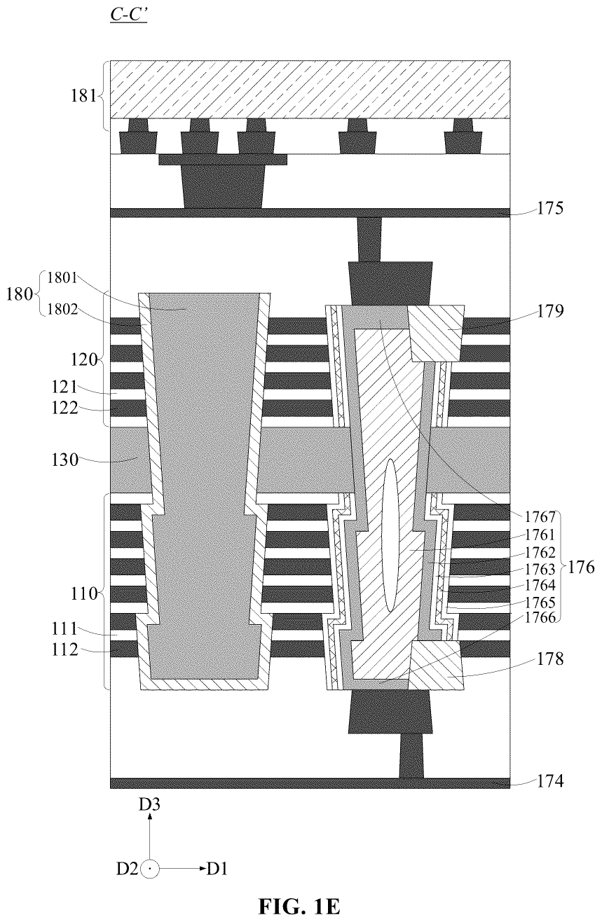

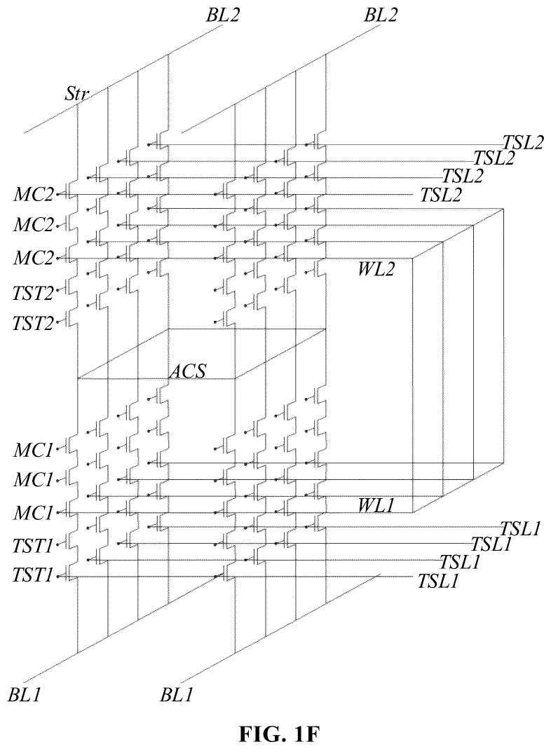

Examples of this disclosure provide a semiconductor structure. FIG. 1A is a cross-sectional view of a semiconductor structure according to an example of the present disclosure. FIG. 1B is a top view of a semiconductor structure according to an example of the present disclosure. FIG. 1C is a perceptive view of a first staircase structure in a semiconductor structure according to an example of the present disclosure. FIG. 1D is a partial enlarged view of a semiconductor structure according to an example of this disclosure. FIG. 1E is a cross-sectional view of a semiconductor structure taken in another plane according to an example of the present disclosure. FIG. 1F is a circuit diagram of a semiconductor structure according to an example of the present disclosure. For example, FIG. 1A may be a cross-sectional view of a semiconductor structure taken along the line A-A′ shown in FIG. 1B. FIG. 1D is a partial enlarged view of region B shown in FIG. 1A. FIG. 1E may be a cross-sectional view taken along line C-C′ shown in FIG. 1B.

It should be noted that, the numbers and dimensions of the components in the foregoing drawings are merely illustrative and used to represent positional relationships between components, and do not represent actual corresponding relationships of components in the drawings. In addition, the directions D1, D2 and D3 in the drawings illustrate the spatial relationship of the components in the semiconductor structure. For example, the direction D3 may be a stacking direction of the first stack structure and the second stack structure, and the directions D1 and D2 may be two directions intersecting (e.g., perpendicular) to each other in a plane intersecting (e.g., perpendicular) to the said stacking direction. For example, the direction D1 may be an extension direction of the first bit line structure (or the second bit line structure). The same concept will be applied throughout this disclosure to describe the spatial relationship of the components in the semiconductor structure.

As shown in FIGS. 1A-1D, the semiconductor structure 100 may comprise a first stack structure 110, a second stack structure 120, a semiconductor layer 130, a first staircase structure 140, a second staircase structure 150, and a connection structure 160. The second stack structure 120 may be located on a side of the first stack structure 110. The semiconductor layer 130 may be located between the first stack structure 110 and the second stack structure 120. The first staircase structure 140 may be located in the first stack structure 110 and comprises a plurality of first step structures 141 arranged along a circumferential direction. The second staircase structure 150 may be located in the second stack structure 120 and comprises a plurality of second step structures 151 arranged along a circumferential direction. The connection structure 160 may extend along the direction D3 and be connected with one first step structure 141 and one second step structure 151.

According to the semiconductor structure 100 provided by the above implementations, the semiconductor layer 130 is disposed between the first stack structure 110 and the second stack structure 120, which can break the limitation of the number of stack layers and help to improve the unit storage density. In addition, the plurality of first step structures 141 arranged along the circumferential direction are disposed in the first staircase structure 140, and the plurality of second step structures 151 arranged along the circumferential direction are disposed in the second staircase structure 150, so that the step area can be effectively reduced, and the problem of increased step area caused by a large number of stack layers is solved, thereby facilitating the reduction of the planar dimension of the semiconductor structure. By connecting the connection structure 160 with one first step structure 141 of the first staircase structures 140 and one second step structure 151 of the second staircase structures 150 disposed in a stack, the step area can be further reduced, and the control difficulty of the semiconductor structure can be reduced.

In some implementations, as shown in FIGS. 1A-1D, from the direction D3, the first stack structure 110 and the second stack structure 120 disposed in a stack may comprise an array region AR and a connection region CR. For example, from the direction D3, the array regions AR of the first stack structure 110 and the second stack structure 120 substantially overlap, and the connection regions CR of the first stack structure 110 and the second stack structure 120 substantially overlap. In some examples, two array regions AR are located on opposite sides of one connection region CR in the direction D2. In other examples, the two connection regions CR may be located on opposite sides (not shown) of one array region AR in the direction D2.

In some implementations, the first stack structure 110 may comprise a first dielectric layer 111 and a first gate layer 112 disposed alternately in the direction D3. For example, the outermost layer of the first stack structure 110 in the direction D3 may be the first dielectric layer 111. The number of the first stack pairs formed by the first dielectric layer 111 and the first gate layer 112 may comprise 32, 64, 128, 258 and more, which is not specifically limited in this disclosure. For example, the first dielectric layer 111 and the first gate layer 112 may extend within the array region AR and at least a portion of the connection region CR.

In some implementations, the material of the first dielectric layer 111 may comprise one or more of silicon oxide, silicon nitride, silicon oxynitride, or any other suitable insulating material. For example, the material of the first dielectric layer 111 may be silicon oxide.

In some implementations, the material of the first gate layer 112 may comprise one or more of titanium, titanium nitride, tantalum, tantalum nitride, polysilicon, amorphous silicon, tungsten, molybdenum, copper, aluminum, ruthenium, metal silicide, or any other suitable conductive material. In some examples, the first gate layer 112 may be made of a single conductive material. In other examples, the first gate layer 112 may comprise a first metal layer and a first adhesive layer (not shown) covering at least a portion of the surface of the first metal layer. For example, the material of the first metal layer may comprise one or more of tungsten, molybdenum, copper, aluminum, ruthenium, or any other suitable metal material. The material of the first adhesive layer may comprise one or more of titanium, titanium nitride, tantalum, tantalum nitride, or any other suitable adhesive material. In an example, at least a portion of the surface of the first adhesive layer may be covered with a first high dielectric constant layer (not shown). The material of the first high dielectric constant layer may comprise, but is not limited to, aluminum oxide, titanium oxide, tantalum oxide, hafnium oxide, and the like.

In some implementations, the second stack structure 120 may comprise a second dielectric layer 121 and a second gate layer 122 disposed alternately in the direction D3. For example, the outermost layer of the second stack structure 120 in the direction D3 may be the second dielectric layer 121. The number of the second stack pairs formed by the second dielectric layer 121 and the second gate layer 122 may comprise 32, 64, 128, 258 and more, which is not specifically limited in this disclosure. It should be noted that the number of the first stack pairs formed by the second dielectric layer 121 and the first gate layer 112 may be the same as or different from the number of the second stack pairs formed by the second dielectric layer 121 and the second gate layer 122, which is not specifically limited in this disclosure. For example, the second dielectric layer 121 and the second gate layer 122 extend within the array region AR and at least a portion of the connection region CR.

In some implementations, the material of the second dielectric layer 121 may comprise one or more of silicon oxide, silicon nitride, silicon oxynitride, or any other suitable insulating material. For example, the material of the second dielectric layer 121 may be silicon oxide.

In some implementations, the material of the second gate layer 122 may comprise one or more of titanium, titanium nitride, tantalum, tantalum nitride, polysilicon, amorphous silicon, tungsten, molybdenum, copper, aluminum, ruthenium, metal silicide, or any other suitable conductive material. In some examples, the second gate layer 122 may be made of a single conductive material. In other examples, the second gate layer 122 may comprise a second metal layer and a second adhesive layer (not shown) covering at least a portion of the surface of the second metal layer. For example, the material of the second metal layer may comprise one or more of tungsten, molybdenum, copper, aluminum, ruthenium, or any other suitable metal material. The material of the second adhesive layer may comprise one or more of titanium, titanium nitride, tantalum, tantalum nitride, or any other suitable adhesive material. In an example, at least a portion of the surface of the second adhesive layer may be covered with a second high dielectric constant layer (not shown). The material of the second high dielectric constant layer may comprise, but is not limited to, aluminum oxide, titanium oxide, tantalum oxide, hafnium oxide, and the like.

In some implementations, the semiconductor layer 130 may extend within the array region AR and the connection region CR. In other implementations, the semiconductor layer 130 may extend within the array region AR without extending within the connection region CR. For example, a portion of the semiconductor layer 130 within the connection region CR may be replaced by an insulating material layer (not shown). The material of the semiconductor layer 130 may comprise one or more of monocrystalline silicon, polysilicon, amorphous silicon, germanium, silicon germanium, metal oxide semiconductor, or any other suitable semiconductor material. For example, the material of the semiconductor layer 130 may be polysilicon. The semiconductor layer 130 (e.g., the portion located within the array region AR) may serve as a common source.

In some implementations, the first staircase structure 140 may be located within the connection region CR. The first stack pair of the first dielectric layer 111 and the first gate layer 112 extends in different dimensions in the connection region CR to form the first staircase structure 140. Thus, the first staircase structure 140 may comprise a first dielectric layer 111 and a first gate layer 112 disposed alternately in the direction D3.

In some implementations, as shown in FIG. 1C, as described above, the first staircase structure 140 may comprise a plurality of first step structures 141 arranged along a circumferential direction c. It should be noted that in the present disclosure, one “step structure” may have two horizontal surfaces and one vertical surface, and the vertical surface may be connected with the edges of the two horizontal surfaces. A “staircase structure” may have a plurality of the above surface combinations. Thus, the “step structure” may be part of a “staircase structure”.

In some implementations, the distance between the two horizontal surfaces of the first step structure 141 may be a multiple of the thickness of the first stack pair (e.g., the dimension in the direction D3). In other words, the distance between the two horizontal surfaces of the first step structure 141 is defined by the thickness of the one or more first stack pairs.

In some implementations, the top layer of the first step structure 141 may be the first gate layer 112. In other words, the surface of the first gate layer 112 may be two horizontal surfaces of the first step structure 141. It should be noted that the “top layer” in this disclosure may be a film layer that constitutes a staircase surface.

In some implementations, in a plane perpendicular to the direction D3, the first staircase structure 140 may comprise a plurality of first step regions SR1 arranged along the circumferential direction c. For example, the plurality of first step regions SR1 may be a plurality of sector regions around the center point. The first step structure 141 may be located within adjacent first step regions SR1. For example, one horizontal surface of the first step structure 141 may be located in a first step region SR1, and another horizontal surface of the first step structure 141 may be located in another first step region SR1 adjacent to the above-mentioned first step region SR1. From the direction D3, the boundary line between the vertical surface of the first step structure 141 and two adjacent first step regions SR1 substantially overlap.

In some implementations, the first step structure 141 may comprise a plurality of first step sub-structures 1411 arranged along the radial direction r. Similarly, a “step sub-structure” may also have two horizontal surfaces and one vertical surface that may be connected with the edges of the two horizontal surfaces. The distance between the two horizontal surfaces of the first step sub-structure 1411 may be a multiple of the thickness of the first stack pair. In other words, the distance between the two horizontal surfaces of the first step sub-structure 1411 is defined by the thickness of the one or more first stack pairs. In this implementation, the plurality of first step sub-structures 1411 arranged along the radial direction r are disposed in the first step structure 141, so that the step area can be further effectively reduced, and the problem of increased step area caused by the large number of stack layers is further improved, so that the planar dimension of the semiconductor structure is further reduced.

In some implementations, the top layer of the first step sub-structure 1411 may be the first gate layer 112. In other words, the surface of the first gate layer 112 may be two horizontal surfaces of the first step sub-structure 1411.

In some implementations, in a plane perpendicular to the direction D3, the first step region SR1 may comprise a plurality of first step sub-regions SSR1 arranged along the radial direction r. For example, in a case where the first step region SR1 is a sector region, the plurality of first step sub-regions SSR1 may be sector regions and annular sector regions arranged coaxially within the sector region. One first step sub-structure 1411 may be located within adjacent first step sub-regions SSR1 in the radial direction r. For example, one horizontal surface of one first step sub-structure 1411 may be located in a first step sub-region SSR1, and another horizontal surface of the first step sub-structure 1411 may be located in another first step sub-region SSR1 adjacent to the above-mentioned first step sub-region SSR1. From the direction D3, the boundary line between the vertical surface of the first step sub-structure 1411 and two adjacent first step sub-regions SSR1 substantially overlap.

In some implementations, with respect to the semiconductor layer 130, the depths of the plurality of first step sub-structures 1411 are different from each other. For example, as shown in FIG. 1A, in a case where the staircase surface of the first staircase structure 140 faces the semiconductor layer 130, the “depth” referred to in this disclosure may be a distance between the semiconductor layer 130 and the one of the two horizontal surfaces of one first step sub-structure 1411 closer to the semiconductor layer 130 in the direction D3 (e.g., I1). In other words, the first gate layers 112 of top layers of the plurality of first step sub-structures 1411 are different from each other.

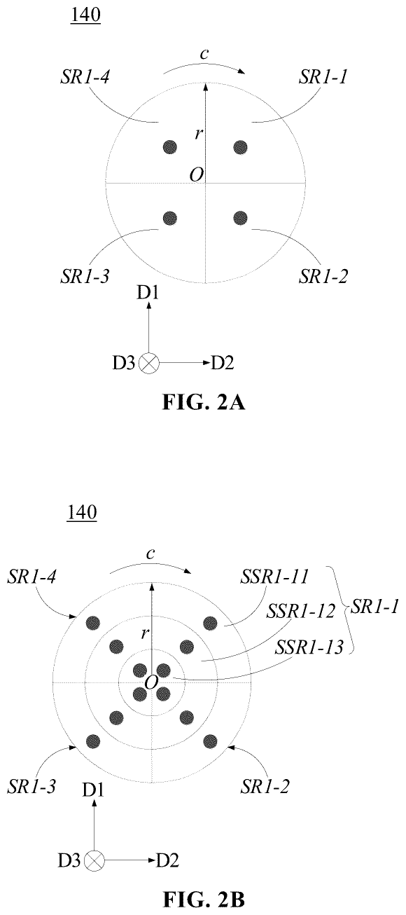

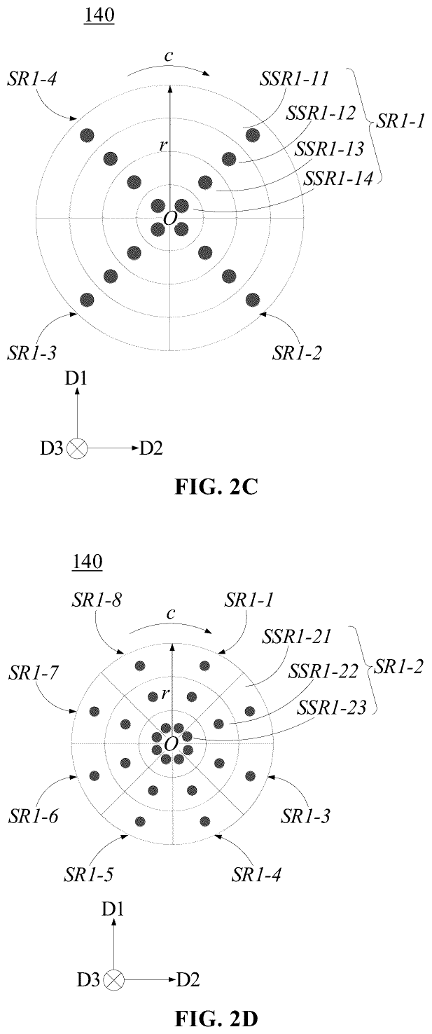

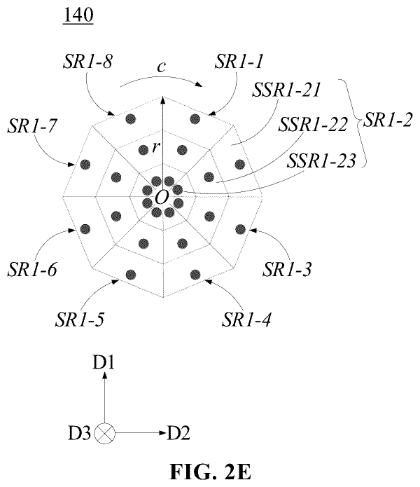

In some implementations, the first step region SR1 and the first step sub-region SSR1 may have a variety of shapes and arrangements. FIG. 2A to FIG. 2E are top views of a first staircase structure according to an example of the present disclosure. Examples are illustrated below.

As shown in FIG. 2A, in a plane perpendicular to the direction D3, the first staircase structure 140 may comprise four first step regions SR1-1, SR1-2, SR1-3, and SR1-4 arranged along the circumferential direction c. The four first step regions SR1-1˜SR1-4 may be four sector regions disposed around the center point O. There is not a first step sub-region within each of the first step regions SR1-1˜SR1-4.

As shown in FIG. 2B, in a plane perpendicular to the direction D3, the first staircase structure 140 may comprise four first step regions SR1-1, SR1-2, SR1-3, and SR1-4 arranged along the circumferential direction c. The four first step regions SR1-1˜SR1-4 may be four sector regions disposed around the center point O. For example, the first step region SR1-1 may comprise three first step sub-regions SSR1-1, SSR1-12, SSR1-13 arranged along the radial direction r. The first step sub-regions SSR1-11 and SSR1-12 may have a substantially annular sector shape, and the first step sub-region SSR1-13 have a substantially sector shape. The first step sub-regions SSR1-11˜SSR1-13 are disposed coaxially with respect to the center point O. Other first step regions SR1-1˜SR1-4 have the same sub-region division as the first step region SR1-1.

As shown in FIG. 2C, in a plane perpendicular to the direction D3, the first staircase structure 140 may comprise four first step regions SR1-1, SR1-2, SR1-3, and SR1-4 arranged along the circumferential direction c. The four first step regions SR1-1˜SR1-4 may be four sector regions disposed around the center point O. For example, the first step region SR1-/may comprise four first step sub-regions SSR1-11, SSR1-12, SSR1-13, and SSR1-14 arranged along the radial direction r. The first step sub-regions SSR1-11˜SSR1-13 have a substantially annular sector shape, and the first step sub-region SSR1-14 have a substantially sector shape. The first step sub-regions SSR1-11˜SSR1-14 are disposed coaxially with respect to the center point O. Other first step regions SR1-1˜SR1-4 have the same sub-region division as the first step region SR1-1.

As shown in FIG. 2D, in a plane perpendicular to the direction D3, the first staircase structure 140 may comprise eight first step regions SR1-1, SR1-2, SR1-3, SR1-4, SR1-5, SR1-6,SR1-7, and SR1-8 arranged along the circumferential direction c. Eight first step regions SR1-1˜SR1-8 may be eight sector regions disposed around the center point O. For example, the first step region SR1-2 may comprise three first step sub-regions SSR1-21, SSR1-22, and SSR1-23 arranged along the radial direction r. The first step sub-regions SSR1-21˜SSR1-22 have a substantially annular sector shape, and the first step sub-region SSR1-23 have a substantially sector shape. The first step sub-regions SSR1-21˜SSR1-23 are disposed coaxially with respect to the center point O. Other first step regions SR1-1 and SR1-3˜SR1-8 have the same sub-region division as the first step region SR1-2.

As shown in FIG. 2E, in a plane perpendicular to the direction D3, the first staircase structure 140 may comprise eight first step regions SR1-1, SR1-2, SR1-3, SR1-4, SR1-5, SR1-6, SR1-7, and SR1-8 arranged along the circumferential direction c. Eight first step regions SR1-1˜SR1-8 may be eight triangular regions disposed around the center point O. For example, the first step region SR1-2 may comprise three first step sub-regions SSR1-21, SSR1-22, and SSR1-23 arranged along the radial direction r. The first step sub-regions SSR1-21˜SSR1-22 may be substantially trapezoidal, and the first step sub-regions SSR1-23 may be substantially triangular. The first step sub-regions SSR1-21˜SSR1-23 are disposed coaxially with respect to the center point O. Other first step regions SR1-1 and SR1-3˜SR1-8 have the same sub-region division as the first step region SR1-2.

It should be noted that, although FIG. 2A to FIG. 2E have shown the shape of the first staircase structure 140 in the direction perpendicular to the direction D3 and the division of the region inside the first staircase structure 140, in some other implementations, the shape of the first staircase structure 140 in the direction perpendicular to the direction D3 may further comprise an ellipse, a square, a hexagon, or any other suitable irregular shape. The shape of the first step region SR1 of the first staircase structure 140 in the direction perpendicular to the direction D3 and the shape of the first step sub-region SSR1 are not specifically limited without departing from the teachings of this disclosure.

In some implementations, referring again to FIGS. 1A and 1B, the second staircase structure 150 may be located within the connection region CR. The second stack pair of the second dielectric layer 121 and the second gate layer 122 extends in a different dimension in the connection region CR to form the second staircase structure 150. Thus, the second staircase structure 150 may comprise a second dielectric layer 121 and a second gate layer 122 disposed alternately in the direction D3.

In some implementations, the distance between the two horizontal surfaces of the second step structure 151 may be a multiple of the thickness of the second stack pair (e.g., the dimension in the direction D3). In other words, the distance between the two horizontal surfaces of the second step structure 151 is defined by the thickness of the one or more second stack pairs.

In some implementations, the top layer of the second step structure 151 may be the second gate layer 122. In other words, the surface of the second gate layer 122 may be two horizontal surfaces of the second step structure 151.

In some implementations, in a plane perpendicular to the direction D3, the second staircase structure 150 may comprise a plurality of second step regions SR2 arranged along the circumferential direction c. For example, the plurality of second step regions SR2 may be a plurality of sector regions around the center point. The second step structure 151 may be located within adjacent second step regions SR2. For example, one horizontal surface of the second step structure 151 may be located in a second step region SR2, and another horizontal surface of the second step structure 151 may be located in another second step region SR2 adjacent to the above-mentioned second step region SR2. From the direction D3, the boundary line between the vertical surface of the second step structure 151 and two adjacent second step regions SR2 substantially overlap.

In some implementations, the second step structure 151 may comprise a plurality of second step sub-structures 1511 arranged along the radial direction r. The distance between the two horizontal surfaces of the second step sub-structure 1511 may be a multiple of the thickness of the second stack pair. In other words, the distance between the two horizontal surfaces of the second step sub-structure 1511 is defined by the thickness of the one or more second stack pairs.

In some implementations, the top layer of the second step sub-structure 1511 may be the second gate layer 122. In other words, the surface of the second gate layer 122 may be two horizontal surfaces of the second step sub-structure 1511.

In some implementations, in a plane perpendicular to the direction D3, the second step region SR2 may comprise a plurality of second step sub-regions SSR2 arranged along the radial direction r. For example, in a case where the second step region SR2 is a sector region, the plurality of second step sub-regions SSR2 may be sector regions and annular sector regions arranged coaxially within the sector region. A second step sub-structure 1511 may be located within adjacent second step sub-regions SSR2 in the radial direction r. For example, one horizontal surface of a second step sub-structure 1511 may be located in the second step sub-region SSR2, and another horizontal surface of the second step sub-structure 1511 may be located in another second step sub-region SSR2 adjacent to the above-mentioned second step sub-region SSR2. From the direction D3, the boundary line between the vertical surface of the second step sub-structure 1511 and two adjacent second step sub-regions SSR2 substantially overlap.

In some implementations, with respect to the semiconductor layer 130, the depths of the plurality of second step sub-structures 1511 are different from each other. For example, as shown in FIG. 1A, in a case where the staircase surface of the second staircase structure 150 faces away from the semiconductor layer 130, the “depth” referred to in this disclosure may be a distance between the semiconductor layer 130 and one of the two horizontal surfaces of the second step sub-structure 1511 farther away from the semiconductor layer 130 in the direction D3 (e.g., I2). In other words, the first gate layers 112 of top layers of the plurality of second step sub-structures 1511 are different from each other.

In some implementations, similar to the first staircase structure 140 shown in FIGS. 2A-2E, in a plane perpendicular to the direction D3, a shape of the second staircase structure 150 in a direction perpendicular to the direction D3 may comprise a circle, an ellipse, a square, a hexagon, an octagon, or any other suitable irregular shape. In addition, the number and shape of the second step region SR2 and the number and shape of the second step sub-region SSR2 are not particularly limited without departing from the teachings of the present disclosure.

In some implementations, the first staircase structure 140 and the second staircase structure 150 are at least partially aligned in the direction D3. For example, from the direction D3, the first staircase structure 140 and the second staircase structure 150 substantially overlap. For another example, from the direction D3, the plurality of first step regions SR1 in the first staircase structure 140 and the plurality of second step regions SR2 in the second staircase structure 150 are in one-to-one correspondence and substantially overlap with each other. For another example, from the direction D3, the plurality of first step sub-regions SSR1 in the first staircase structure 140 and the plurality of second step sub-regions SSR2 in the second staircase structure 150 are in one-to-one correspondence and substantially overlap with each other.

It should be noted that the staircase surfaces of the first staircase structure 140 may have a trend of sequential increase or sequential decrease, or alternatively have a trend of staggered increase or staggered decrease. Similarly, the staircase surfaces of the second staircase structures 150 may also have a trend of sequential increase or sequential decrease, or alternatively have a trend of staggered increase or staggered decrease. In addition, the trend of the staircase surfaces of the first staircase structure 140 and the second staircase structure 150 may be the same or different.

In some implementations, there may be a plurality of first staircase structure 140 and a plurality of second staircase structure 150. From the direction D3, the first staircase structure 140 and the second staircase structure 150 may be arranged in rows along the direction D2. For example, the first staircase structure 140 and the second staircase structure 150 may have one or more rows.

In some implementations, the first gate layers 112 of top layers of the plurality of first step sub-structures 1411 in each of the first staircase structures 140 are different from each other. The second gate layers 122 of top layers of the plurality of second step sub-structures 1511 in each of the second staircase structures 150 are different from each other. Thus, the staircase surfaces of each of the first staircase structures 140 may expose a plurality of different first gate layers 112 in the first stack structure 110, and the staircase surfaces of each of the second staircase structures 150 may expose a plurality of different second gate layers 122 in the second stack structure 120.

In some implementations, the semiconductor structure 100 may further comprise a first insulating structure 171 and a second insulating structure 172. The first insulating structure 171 may be located on a side of the first staircase structure 140 close to the semiconductor layer 130. The second insulating structure 172 may be located on a side of the second staircase structure 150 away from the semiconductor layer 130. For example, the first insulating structure 171 may have another staircase surface that matches the staircase surface of the first staircase structure 140. A staircase surface of the first insulating structure 171 faces away from the semiconductor layer 130. A surface of the first insulating structure 171 away from the semiconductor layer 130 may be substantially planar, and may be substantially aligned with a surface of the first stack structure 110 towards the semiconductor layer 130. Similarly, the second insulating structure 172 may have yet another staircase surface that matches the staircase surface of the second staircase structure 150. A surface of the second insulating structure 172 away from the semiconductor layer 130 may be substantially planar, and may be substantially aligned with a surface of the second stack structure 120 away from the semiconductor layer 130.

In some implementations, the material of the first insulating layer 171 may comprise one or more of silicon oxide, silicon nitride, silicon oxynitride, or any other suitable insulating material. The material of the second insulating structure 172 may also comprise one or more of silicon oxide, silicon nitride, silicon oxynitride, or any other suitable insulating material. The materials of the first insulating structure 171 and the second insulating structure 172 may be the same or different. For example, both the first insulating structure 171 and the second insulating structure 172 may be made of silicon oxide. In a case where the portion of the semiconductor layer 130 located at the connection region CR is replaced by the insulating material layer, and the materials of the insulating material layer and the first insulating structure 171 are the same, there is no obvious interface between the insulating material layer and the first insulating structure 171, and the insulating material layer and the first insulating structure 171 may be an integral structure.

In some implementations, the connection structure 160 may be substantially a columnar structure extending continuously in the direction D3. For example, the connection structure 160 may extend through the second insulating structure 172, the second staircase structure 150, the semiconductor layer 130 (or the insulating material layer), the first insulating structure 171, and the first staircase structure 140. For example, in a case where the first step region SR1 does not have the first step sub-region SSR1 and the second step region SR2 does not have the second step sub-region SSR2, from the direction D3, the connection structure 160 may be located within one first step region SR1 and one second step region SR2. Thus, the connection structure 160 may be connected with one first step structure 141 and connected with one second step structure 151. For another example, in a case where the first step region SR1 has a first step sub-region SSR1 and the second step region SR2 has a second step sub-region SSR2, from the D3 direction, the connection structure 160 may be located in one first step sub-region SSR1 and one second step sub-region SSR2. Thus, the connection structure 160 may be connected with one first step sub-structure 1411 and connected with one second step sub-structure 1511.

In some implementations, the material of the connection structure 160 may comprise one or more of titanium, titanium nitride, tantalum, tantalum nitride, polysilicon, amorphous silicon, tungsten, molybdenum, copper, aluminum, ruthenium, metal silicide, or any other suitable conductive material.

In some implementations, as shown in FIGS. 1A and ID, the semiconductor structure 100 may further comprise an isolation layer 173. The isolation layer 173 may surround a portion of the connection structure 160 extending through the first staircase structure 140 and the second staircase structure 150. For example, the isolation layer 173 may comprise a first isolation portion 1731 and a second isolation portion 1732. The first isolation portion 1731 and second isolation portion 1732 may be substantially tubular. The first isolation portion 1731 may be sleeved at a portion of the connection structure 160 extending through the first staircase structure 140. For example, the inner side of the first isolation portion 1731 may be in contact with the connection structure 160, and the outer side may be in contact with the first staircase structure 140. The second isolation portion 1732 may be sleeved at a portion of the connection structure 160 extending through the second staircase structure 150. For example, the inner side of the second isolation portion 1732 may be in contact with the connection structure 160, and the outer side may be in contact with the second staircase structure 150. The material of the isolation layer 173 may comprise one or more of silicon oxide, silicon nitride, silicon oxynitride, or any other suitable insulating material.

In some implementations, the isolation layer 173 may also surround a portion of the connection structure 160 extending through the first insulating structure 171 and the second insulating structure 172. In a case where the material of the isolation layer 173 is the same as the material of the first insulating structure 171, there is no obvious interface between them, and they may be an integral structure. Similarly, in a case where the material of the isolation layer 173 and the material of the second isolation structure 172 are the same, there is no obvious interface between them, and they may be an integral structure.

In some implementations, in a plane perpendicular to the direction D3, a dimension d2 of a portion of the connection structure 160 extending through the first insulating structure 171 is greater than a dimension d1 of a portion of the connection structure 160 extending through the first staircase structure 140. For example, dimension d1 may be a maximum dimension of a portion of the connection structure 160 extending through the first staircase structure 140 in a plane perpendicular to the direction D3. The dimension d2 may be a minimum dimension of a portion of the connection structure 160 extending through the first insulating structure 171 in a plane perpendicular to the direction D3. Thus, a portion of the connection structure 160 with a large dimension in a plane perpendicular to the direction D3 extending through the first insulating structure 171 may be connected with one first gate layer 112 in the first step sub-structure 1411, for example, in contact with the first gate layer 112 of the top layer.

In some implementations, in a plane perpendicular to the direction D3, a (e.g., minimum) dimension of a portion of the connection structure 160 extending through the second insulating structure 172 is greater than a (e.g., maximum) dimension of a portion of the connection structure 160 extending through the second staircase structure 150. Thus, a portion of the connection structure 160 with a large dimension in a plane perpendicular to the direction D3 extending through the second insulating structure 172 may be connected with one second gate layer 122 in the second step sub-structure 1511, for example, in contact with the second gate layer 122 of the top layer.

In the above implementation, one connection structure 160 can lead out a first gate layer 112 and a second gate layer 122, and the first gate layer 112 and the second gate layer 122 can be connected with each other by a connection structure 160. The isolation layer 173 can electrically isolate the connection structure 160 from other first gate layers 112 in the non-top layer in the first step sub-structure 1411 and other second gate layers 122 in the non-top layer in the second step sub-structure 1511.

In some implementations, as shown in FIG. 1A, the connection structure 160 may comprise a plurality of connection sub-structures 163 arranged along the direction D3. The dimension (e.g., diameter) of the connection sub-structure 163 in a plane perpendicular to the direction D3 may increase gradually along the direction D3. In this implementation, a plurality of connection sub-structures 163 are disposed to help reduce the difficulty of manufacturing the connection structure 160 and improve the yield of the connection structure 160.

In some implementations, as shown in FIG. 1E, the semiconductor structure 100 may further comprise a first bit line structure 174 and a second bit line structure 175. The first bit line structure 174 may be located on a side of the first stack structure 110 away from the semiconductor layer 130. The second bit line structure 175 may be located on a side of the second stack structure 120 away from the semi-conductive layer 130. The first bit line structure 174 and the second bit line structure 175 may extend in the direction D1. For example, the first bit line structure 174 may comprise a plurality of first bit line structures 174, and the plurality of first bit line structures 174 may be spaced apart from each other in the direction D2. The second bit line structure 175 may comprise a plurality of second bit line structures 175, and the plurality of second bit line structures 175 may be spaced apart from each other in the direction D2. For another example, both the plurality of first bit line structures 174 and the plurality of second bit line structures 175 may be located in the array region AR.

In some implementations, the material of the first bit line structure 174 may comprise one or more of titanium, titanium nitride, tantalum, tantalum nitride, polysilicon, amorphous silicon, tungsten, molybdenum, copper, aluminum, ruthenium, metal silicide, or any other suitable conductive material. The material of the second bit line structure 175 may comprise one or more of titanium, titanium nitride, tantalum, tantalum nitride, polysilicon, amorphous silicon, tungsten, molybdenum, copper, aluminum, ruthenium, metal silicide, or any other suitable conductive material. For example, the materials of the first bit line structure 174 and the second bit line structure 175 are both tungsten.

In some implementations, the semiconductor structure 100 may further comprise a first channel structure 176. The first channel structure 176 may extend through the second stack structure 120, the semiconductor layer 130 and the first stack structure 110, and may be connected with the first bit line structure 174 and the second bit line structure 175. For example, the first channel structure 176 may be substantially columnar. The first channel structure 176 may comprise a first insulating pillar 1761, a first channel layer 1762, a first tunneling layer 1763, a first charge trapping layer 1764, and a first blocking layer 1765. The first insulating pillar 1761 may extend along the direction D3 in the first stack structure 110, the semiconductor layer 130, and the second stack structure 120. The first channel layer 1762 may surround the first insulating pillar 1761. The first tunneling layer 1763 may surround a portion of the first channel layer 1762 extending through the first stack structure 110 and the second stack structure 120. The first charge trapping layer 1764 may surround the first tunneling layer 1763. The first blocking layer 1765 may surround the first charge trapping layer 1764. Thus, the semiconductor layer 130 may directly surround the first channel layer 1762. In other words, the semiconductor layer 130 may be in contact with the first channel layer 1762. In an example, the first channel structure 176 may further comprise a first channel plug 1766 and a second channel plug 1767. The first channel plug 1766 and the second channel plug 1767 may be located at two ends of the first insulating pillar 1761 respectively in the direction D3, and are in contact with the first channel layer 1762. The first channel plug 1766 may be connected with the first bit line structure 174 (e.g., through an interconnect line and/or an interconnection channel), and the second channel plug 1767 may be connected (e.g., through an interconnect line and/or an interconnection channel) to the second bit line structure 175. In this implementation, the channel length of the first channel structure 176 can be reduced and the conduction current Iₒₙ can be improved.

In some implementations, the material of the first insulating pillar 1761 may comprise one or more of silicon oxide, silicon nitride, silicon oxynitride, or any other suitable insulating material. For example, the material of the first insulating pillar 1761 may be silicon oxide. The material of the first channel layer 1762 may comprise one or more of monocrystalline silicon, polysilicon, amorphous silicon, germanium, germanium silicon, metal oxide semiconductor (e.g., indium gallium zinc oxide), or any other suitable semiconductor material. For example, the material of the first channel layer 1762 may be polysilicon. The materials of the first tunneling layer 1763, the first charge trapping layer 1764, and the first blocking layer 1765 may sequentially comprise silicon oxide, silicon nitride, and silicon oxide. The material of the first channel plug 1766 and the second channel plug 1767 may be the same as the material of the first channel layer 1762. In this case, there is no obvious interface between the three materials, and they may be an integral structure.

In some implementations, the first channel structure 176 may comprise a plurality of first channel structures 176. As shown in FIG. 1B, the plurality of first channel structures 176 may be located in the array region AR and may be arranged in an array in the directions D1 and D2. The first channel structure 176 may be configured to achieve a storage function.

In some implementations, the semiconductor structure 100 may further comprise a first selective gate cut line structure 178. The first selective gate cut line structure 178 may extend through several first gate layers 112 from a side of the first stack structure 110 away from the semiconductor layer 130, and through a portion of the first channel structure 176, for example. For example, the number of the first gate layers 112 through which the first selective gate cut line structure 178 extends may be 1 to 5. The first selective gate cut line structure 178 may also extend in the direction D2 (e.g., within the array region AR). For example, a plurality of first selective gate cut line structures 178 may be spaced apart from each other along the direction D1. The material of the first selective gate cut line structure 178 may comprise one or more of silicon oxide, silicon nitride, silicon oxynitride, or any other suitable insulating material. For example, the material of the first selective gate cut line structure 178 may be silicon oxide.

In some implementations, the semiconductor structure 100 may further comprise a second selective gate cut line structure 179. The second selective gate cut line structure 179 may extend through several second gate layers 122 from a side of the second stack structure 120 away from the semiconductor layer 130, and through a portion of the first channel structure 176, for example. For example, the number of the second gate layers 122 through which the second selective gate cut line structure 179 extends may be 1 to 5. The second selective gate cut line structure 179 may also extend in the direction D2 (e.g., within the array region AR). For example, a plurality of first selective gate cut line structures 178 may be spaced apart from each other along the direction D1. The material of the second selective gate cut line structure 179 may comprise one or more of silicon oxide, silicon nitride, silicon oxynitride, or any other suitable insulating material. For example, the material of the second selective gate cut line structure 179 may be silicon oxide.

In some implementations, as shown in FIGS. 1E and 1F, a portion of the first channel structure 176 surrounded by a first gate layer 112 through which one first selective gate cut line structure 178 extends and a portion of the first gate layer 112 constitute one first selective transistor TST1. Other portions of the first gate layer 112 may serve as the first selective line TSL1. A portion of the first channel structure 176 surrounded by one of the other first gate layers 112 and a portion of the first gate layer 112 constitute one first memory cell MC1. Other portions of the first gate layer 112 may serve as the first word line WL1.

A portion of the first channel structure 176 surrounded by one second gate layer 122 through which the second selective gate cut line structure 179 extends and a portion of the second gate layer 122 constitute a second selective transistor TST2. Other portions of the second gate layer 122 may serve as the second selective line TSL2. A portion of the first channel structure 176 surrounded by one of the other second gate layers 122 and a portion of the second gate layer 122 constitute a second memory cell MC2. Other portions of the second gate layer 122 may serve as the second word line WL2. As described in detail above, the connection structure 160 may connect one first word line WL1 and one second word line WL2 to each other.

A plurality of memory cells (e.g., the first memory cell MC1 and the second memory cell MC2), at least one first selective transistor TST1, and at least one second selective transistor TST2 are arranged in series along an extension direction (e.g., D3 direction) of the first channel structure 176 to form a memory string Str and share the first channel layer 1762. The two ends of the memory string Str are connected with the bit lines BL1 and BL2 (corresponding to the first bit line structure 174 and the second bit line structure 175) respectively, and the common source line ACS (corresponding to the semiconductor layer 130) is connected between the first memory cell MC1 and the second memory cell MC2 in the memory string Str.

In some implementations, as shown in FIG. 1B, the semiconductor structure 100 may further comprise a second channel structure 177. The second channel structure 177 may extend through the second staircase structure 150 and the first staircase structure 140. For example, the second channel structure 177 may be substantially columnar, and its internal structure is the same as the first channel structure 176, which will not be described herein in detail. Further, the second channel structure 177 may be located within the connection region CR and not connected with the first bit line structure 174 and the second bit line structure 175. The second channel structure 177 may be configured to provide mechanical support and/or load balancing.

In some implementations, as shown in FIGS. 1B and 1E, the semiconductor structure 100 may further comprise a gate line isolation structure 180. The gate line isolation structure 180 may extend through the second stack structure 120, the semiconductor layer 130, and the first stack structure 110. The gate line isolation structures 180 may extend in the direction D2 (e.g., within the array region AR and the connection region CR). A plurality of gate line isolation structures 180 may be spaced apart from each other in the direction D1. For example, two adjacent gate line isolation structures 180 may separate the first stack structure 110 and the second stack structure 120 into memory blocks BLK. For example, the first gate layer 112, the second gate layer 122, and the semiconductor layer 130 on both sides of the gate line isolation structure 180 in the direction D1 are electrically isolated.

In some implementations, the gate line isolation structure 180 may comprise a polysilicon body 1801 and an oxide layer 1802. Polysilicon body 1801 may extend through the second stack structure 120, semiconductor layer 130, and first stack structure 110 and extend through in the direction D2 (e.g., within array region AR and connection region CR). The oxide layer 1802 may be located on opposite sidewalls of the polysilicon body 1801 in the direction D1, and the polysilicon body 1801 is located on an end surface of the first stack structure 110. For example, the material of the oxide layer 1802 may comprise silicon oxide. The gate line isolation structure 180 is made of the above two materials, which helps to save cost and balance stress. In other implementations, the gate line isolation structure 180 may be made of a single insulating material, which is not limited in the present disclosure.

In some implementations, the semiconductor structure 100 may further comprise a peripheral circuit structure 181. For example, the peripheral circuit structure 181 may be located on a side of the second stack structure 120 away from the semiconductor layer 130. In other implementations, the peripheral circuit structure 181 may be located on a side (not shown) of the first stack structure 110 away from the semiconductor layer 130. Peripheral circuit structure 181 may comprise any suitable digital, analog, and/or mixed-signal peripheral circuit for controlling the operation of a memory cell array (e.g., a memory cell array composed of first memory cell MC1 and second memory cell MC2). For example, the peripheral circuit may comprise one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portion (e.g., sub-circuit) of the aforementioned functional circuit, or any active or passive component (e.g., transistor, diode, resistor, or capacitor) of the circuit.

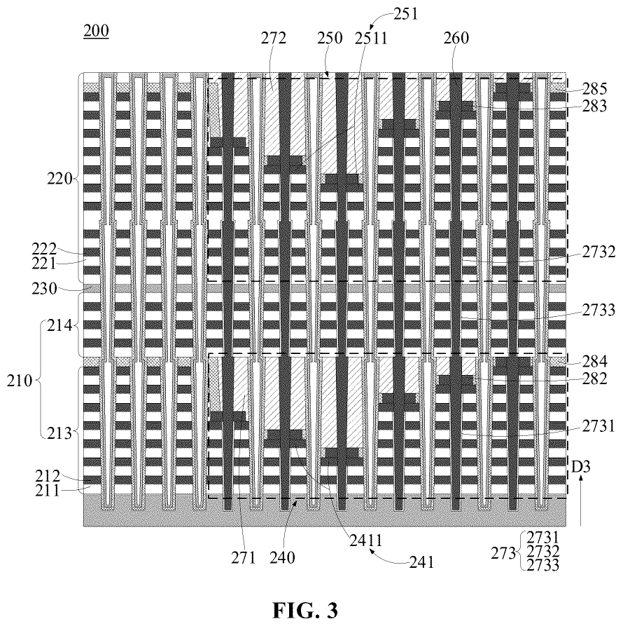

FIG. 3 is a cross-sectional view of a semiconductor structure according to another example of the present disclosure. For ease of description, in this example and the following examples, the same content as the previous example will not be described herein again.

As shown in FIG. 3, the semiconductor structure 200 may comprise a first stack structure 210, a second stack structure 220, a semiconductor layer 230, a first staircase structure 240, a second staircase structure 250, and a connection structure 260. The second stack structure 220 may be located on a side of the first stack structure 210. The semiconductor layer 230 may be located between the first stack structure 210 and the second stack structure 220. The first staircase structure 240 may be located in the first stack structure 210 and comprises a plurality of first step structures 241 arranged along a circumferential direction. The second staircase structure 250 may be located in the second stack structure 220 and comprises a plurality of second step structures 251 arranged along a circumferential direction. The connection structure 260 may extend along the direction D3 and may be connected with one first step structure 241 and one second step structure 251.

In some implementations, the first stack structure 210 may comprise a first dielectric layer 211 and a first gate layer 212 disposed alternately in the direction D3. For example, the first stack structure 210 may comprise a first stack portion 213 and a second stack portion 214 arranged along the direction D3. The first stack portion 213 and the second stack portion 214 may each comprise a first dielectric layer 211 and a first gate layer 212 disposed alternately. The first staircase structure 240 may be located in the first stack portion 213. Similarly, the second stack structure 220 may comprise a second dielectric layer 221 and a second gate layer 222 disposed alternately in the direction D3.

In some implementations, the first step structure 241 may comprise a plurality of first step sub-structures 2411 arranged along a radial direction. The second staircase structure 251 may comprise a plurality of second step sub-structures 2511 arranged along a radial direction.

In some implementations, the semiconductor structure 200 may further comprise a first insulating structure 271 and a second insulating structure 272. The first insulating structure 271 may be located on a side of the first staircase structure 240 close to the semiconductor layer 230. The second insulating structure 272 may be located on a side of the second staircase structure 250 away from the semiconductor layer 230. In a case where the first stack structure 210 comprises the first stack portion 213 and the second stack portion 214 and the first staircase structure 240 is located in the first stack portion 213, the second stack portion 214 may cover the first insulating structure 271. In other words, the first insulating structure 271 may be filled in at least a portion of the cavity between the second stack portion 214 and the first staircase structure 240.

In some implementations, the connection structure 260 may be substantially a columnar structure extending continuously in the direction D3. For example, the connection structure 260 may extend through the second insulating structure 272, the second staircase structure 250, the semiconductor layer 230 (or the insulating material layer), the first insulating structure 271, and the first staircase structure 240. In a case where the first stack structure 210 comprises the first stack portion 213 and the second stack portion 214 and the first staircase structure 240 is located in the first stack portion 213, the connection structure 260 may sequentially extend through the second insulating structure 272, the second staircase structure 250, the semiconductor layer 230 (or the insulating material layer), the second stack portion 214, the first insulating structure 271, and the first staircase structure 240.

In some implementations, the semiconductor structure 200 may further comprise a first surrounding portion 282. The first surrounding portion 282 may surround the connection structure 260 and contact the first staircase structure 240. For example, the first surrounding portion 282 may be sleeved at the connection structure 260 and may be in contact with the connection structure 260. In a plane perpendicular to the direction D3, an outer diameter of the first surrounding portion 282 may be greater than a dimension of a portion of the connection structure 260 extending through the first staircase structure 240, and greater than a dimension of a portion of the connection structure 260 extending through the first insulating structure 271. The dimension of the first surrounding portion 282 in the direction D3 may be substantially the same as the dimension of the first dielectric layer 211 in the direction D3. The first surrounding portion 282 may be in contact with the first gate layer 212 of the top layer of one first step structure 241 (or one first step sub-structure 2411). In addition, from the direction D3, the first surrounding portion 282 may be located within a region defined by one horizontal surface of one first step structure 241 (or one first step sub-structure 2411).

In some implementations, the material of the first surrounding portion 282 may comprise one or more of titanium, titanium nitride, tantalum, tantalum nitride, polysilicon, amorphous silicon, tungsten, molybdenum, copper, aluminum, ruthenium, metal silicide, or any other suitable conductive material. For example, the material of the first surrounding portion 282 may be the same as the material of the connection structure 260, and in this case there is no obvious interface between them, and they may be an integral structure.

In some implementations, the semiconductor structure 200 may further comprise a second surrounding portion 283. The second surrounding portion 283 may surround the connection structure 260 and contact the second staircase structure 250. For example, the second surrounding portion 283 may be sleeved at the connection structure 260 and may be in contact with the connection structure 260. In a plane perpendicular to the direction D3, an outer diameter of the second surrounding portion 283 may be greater than a dimension of a portion of the connection structure 260 extending through the second staircase structure 250, and may be greater than a dimension of a portion of the connection structure 260 extending through the second insulating structure 272. The dimension of the first surrounding portion 282 in the direction D3 may be substantially the same as the dimension of the second dielectric layer 221 in the direction D3. The second surrounding portion 283 may be in contact with the second gate layer 222 of the top layer of one second step structure 251 (or one second step sub-structure 2511). In addition, from the direction D3, the second surrounding portion 283 may be located within a region defined by one horizontal surface of one second step structure 251 (or one first step sub-structure 2511).

In some implementations, the material of the second surrounding portion 283 may comprise one or more of titanium, titanium nitride, tantalum, tantalum nitride, polysilicon, amorphous silicon, tungsten, molybdenum, copper, aluminum, ruthenium, metal silicide, or any other suitable conductive material. For example, the material of the second surrounding portion 283 may be the same as the material of the connection structure 260, and in this case there is no obvious interface between them, and they may be an integral structure. The materials of the first surrounding portion 282 and the second surrounding portion 283 may be the same or different.

In some implementations, the semiconductor structure 200 may further comprise an isolation layer 273. The isolation layer 273 may surround a portion of the connection structure 260 extending through the first staircase structure 240 and the second staircase structure 250. For example, the isolation layer 273 may comprise a first isolation portion 2731 and a second isolation portion 2732. The first isolation portion 2731 may be sleeved at a portion of the connection structure 260 extending through the first staircase structure 240. The second isolation portion 2732 may be sleeved at a portion of the connection structure 260 extending through the second staircase structure 250. In a case where the first stack structure 210 comprises the first stack portion 213 and the second stack portion 214 and the first staircase structure 240 is located in the first stack portion 213, the isolation layer 273 may further comprise a third isolation portion 2733. The third isolation portion 2733 may surround a portion of the connection structure 260 extending through the second stack portion 214.

As described above, one connection structure 260 can lead out one first gate layer 212 and one second gate layer 222, the first gate layer 212 and the second gate layer 222 can be connected with each other by a connection structure 260. The isolation layer 273 can electrically isolate the connection structure 260 from other first gate layers 212 in the non-top layer in the first step structure 241 (or the first step sub-structure 2411), and other second gate layers 222 in the non-top layer in the second step structure 251 (or the second step sub-structure 2511). In an example, the isolation layer 273 can further electrically isolate the connection structure 260 from the first gate layer 212 in the second stack portion 214.

In some implementations, the semiconductor structure 200 further comprises a first insulating layer 284. The first insulating layer 284 may be located between the first staircase structure 240 and the first insulating structure 271. For example, the first insulating layer 284 may cover a staircase surface of the first staircase structure 240. A thickness of the first insulating layer 284 (e.g., a dimension in a direction perpendicular to the staircase surface) may be substantially the same as a dimension of the first surrounding portion 282 in the direction D3. The first surrounding portion 282 may be embedded in the first insulating layer 284. The material of the first insulating layer 284 may comprise one or more of silicon oxide, silicon nitride, silicon oxynitride, or any other suitable insulating material. For example, a material of the first insulating layer 284 may be different from a material of the first dielectric layer 211. In a case where the material of the first dielectric layer 211 is silicon oxide, the material of the first insulating layer 284 may comprise silicon nitride, such as carbon-doped silicon nitride.

In some implementations, the semiconductor structure 200 may further comprise a second insulating layer 285. The second insulating layer 285 may be located between the second staircase structure 250 and the second insulating structure 272. For example, the second insulating layer 285 may cover a staircase surface of the second staircase structure 250. A thickness of the second insulating layer 285 (e.g., a dimension in a direction perpendicular to the staircase surface) may be substantially the same as a dimension of the second surrounding portion 283 in the direction D3. The second surrounding portion 283 may be embedded in the second insulating layer 285. The material of the second insulating layer 285 may comprise one or more of silicon oxide, silicon nitride, silicon oxynitride, or any other suitable insulating material. For example, a material of the second insulating layer 285 may be different from a material of the second dielectric layer 221. In a case where the material of the second dielectric layer 221 is silicon oxide, the material of the second insulating layer 285 may be silicon nitride, such as carbon-doped silicon nitride.

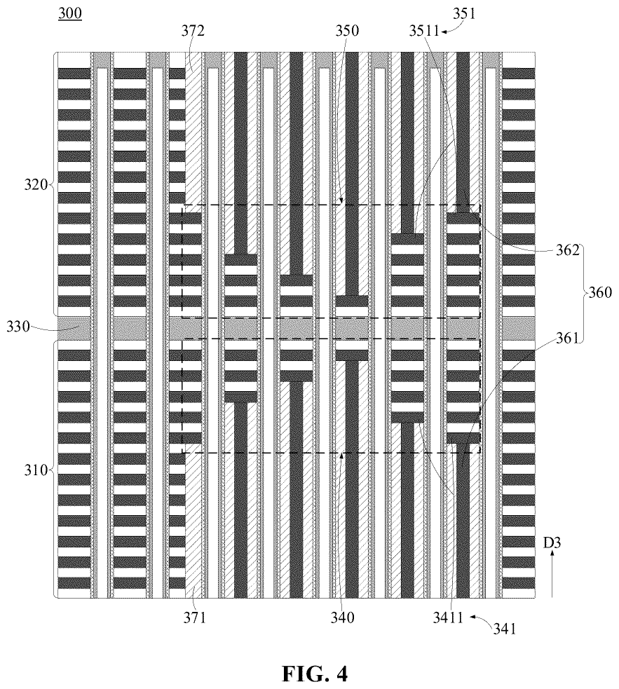

FIG. 4 is a cross-sectional view of a semiconductor structure according to another example of the present disclosure. As shown in FIG. 4, the semiconductor structure 300 may comprise a first stack structure 310, a second stack structure 320, a semiconductor layer 330, a first staircase structure 340, a second staircase structure 350, and a connection structure 360. The second stack structure 320 may be located on a side of the first stack structure 310. The semiconductor layer 330 may be located between the first stack structure 310 and the second stack structure 320. The first staircase structure 340 may be located in the first stack structure 310 and comprises a plurality of first step structures 341 arranged along a circumferential direction. The second staircase structure 350 may be located in the second stack structure 320 and comprises a plurality of second step structures 351 arranged along a circumferential direction. The connection structure 360 may extend along the direction D3 and be connected with one first step structure 341 and one second step structure 351.

In some implementations, the first stack structure 310 may comprise a first dielectric layer 311 and a first gate layer 312 disposed alternately in the direction D3. Similarly, the second stack structure 320 may comprise a second dielectric layer 321 and a second gate layer 322 disposed alternately in the direction D3.

In some implementations, the first step structure 341 may comprise a plurality of first step sub-structures 3411 arranged along the radial direction. The second staircase structure 351 may comprise a plurality of second step sub-structures 3511 arranged along a radial direction. For example, the first insulating structure 371 may have another staircase surface that matches the staircase surface of the first staircase structure 340. A staircase surface of the first insulating structure 371 faces the semiconductor layer 330. A surface of the first insulating structure 371 away from the semiconductor layer 330 may be substantially planar, and may be substantially aligned with a surface of the first stack structure 310 away from the semiconductor layer 330. Similarly, the second insulating structure 372 may have yet another staircase surface that matches the staircase surface of the second staircase structure 350. A staircase surface of the second insulating structure 372 faces the semiconductor layer 330. A surface of the second insulating structure 372 away from the semiconductor layer 330 may be substantially planar, and may be substantially aligned with a surface of the second stack structure 320 away from the semiconductor layer 330.

In some implementations, the connection structure 360 may comprise a first connecting portion 361 and a second connecting portion 362. The first connecting portion 361 may extend through the first insulating structure 371 and extend to the first staircase structure 340. The second connecting portion 362 may extend through the second insulating structure 372 and extend to the second staircase structure 350. For example, the first connecting portion 361 and the second connecting portion 362 may be structures separated from each other. The first connecting portion 361 may be a columnar structure extending substantially in the direction D3 continuously, and the second connecting portion 362 may also be a columnar structure extending substantially in the direction D3 continuously. In the direction D3, the first connecting portion 361 and the second connecting portion 362 may be substantially aligned. In other words, from the direction D3, the first connecting portion 361 and the second connecting portion 362 may substantially overlap. Further, the first connecting portion 361 may be located within a region defined by one horizontal surface of the first step structure 341 (or the first step sub-structure 3411). The second connecting portion 362 may be located within a region defined by one horizontal surface of the second step structure 351 (or the second step sub-structure 3511). Thus, the first connecting portion 361 may be connected with one first step structure 341 (or the first step sub-structure 3411), and the second connecting portion 362 may be connected with one second step structure 351 (or the second step sub-structure 3511).

In the above implementation, the first connecting portion 361 can lead out the first gate layer 312 of the top layer in one first step structure 341 (or the first step sub-structure 3411), and the second connecting portion 362 can lead out the second gate layer 322 of the top layer in one second step structure 351 (or the second step sub-structure 3511). For example, the first connecting portion 361 and the second connecting portion 362 may be connected with each other, for example, through interconnecting wires and/or interconnecting channels. For another example, the first connecting portion 361 and the second connecting portion 362 may not be connected with each other, such that each first gate layer 312 and each second gate layer 322 can be controlled individually.

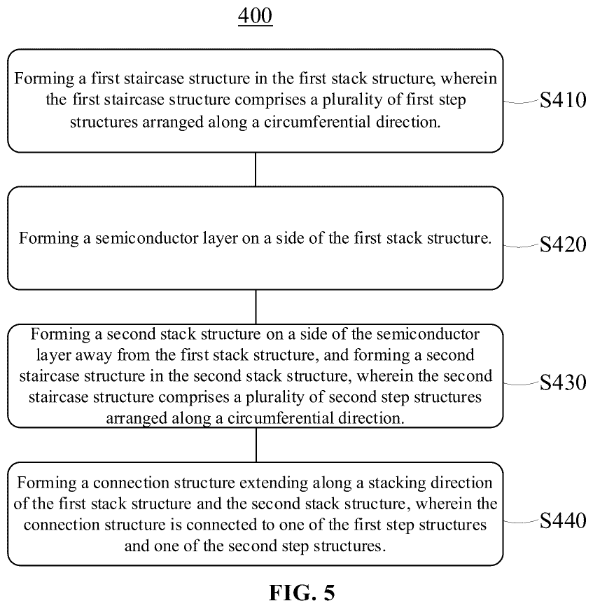

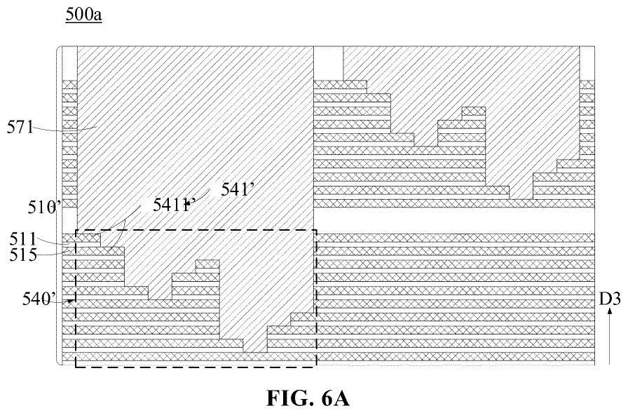

Examples of the present disclosure also provide a manufacturing method of a semiconductor structure. FIG. 5 is a process diagram of the manufacturing method of a semiconductor structure according to an example of the present disclosure. As shown in FIG. 5, a manufacturing method 400 of a semiconductor structure (hereinafter referred to as a manufacturing method 400) may comprise the following steps.
S410: forming a first staircase structure in the first stack structure, wherein the first staircase structure comprises a plurality of first step structures arranged along a circumferential direction.
S420: forming a semiconductor layer on a side of the first stack structure.
S430: forming a second stack structure on a side of the semiconductor layer away from the first stack structure, and forming a second staircase structure in the second stack structure, wherein the second staircase structure comprises a plurality of second step structures arranged along the circumferential direction.
S440: forming a connection structure extending along a stacking direction of the first stack structure and the second stack structure, wherein the connection structure is connected with one of the first step structures and one of the second step structures.

According to the manufacturing method provided by examples of this disclosure, the semiconductor layer is formed between the first stack structure and the second stack structure, which may break through the limitation of the number of stack layers, and improve the unit storage density. In addition, a plurality of first step structures arranged along the circumferential direction are disposed in the first staircase structure, and a plurality of second step structures arranged along the circumferential direction are disposed in the second staircase structure, so that the step area can be effectively reduced, and the problem of increased step arca caused by the large number of stack layers is solved, thereby facilitating the reduction of the planar dimension of the semiconductor structure. By forming the connection structure connected respectively with one of the first staircase structures and one of the second staircase structures stacked together, the step area can be further reduced, and the control difficulty of the semiconductor structure can also be reduced.

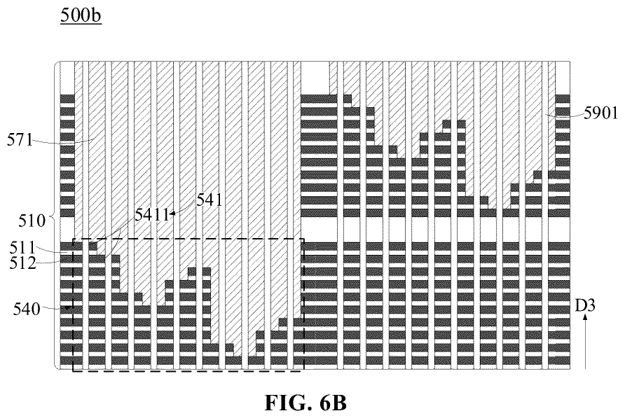

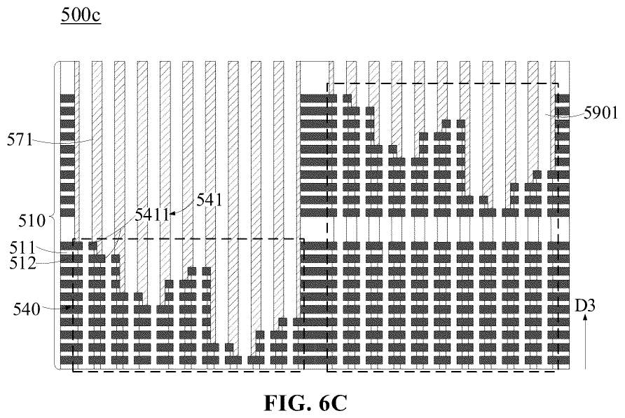

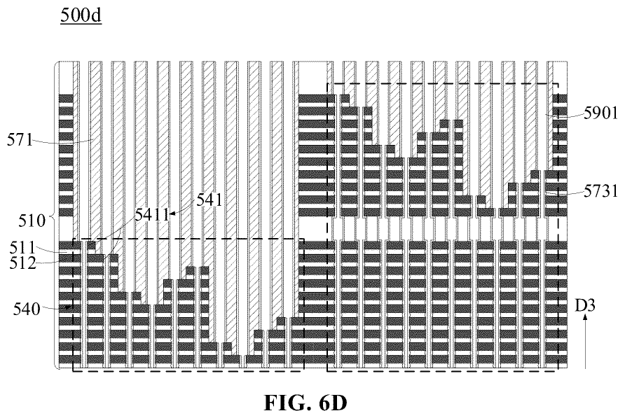

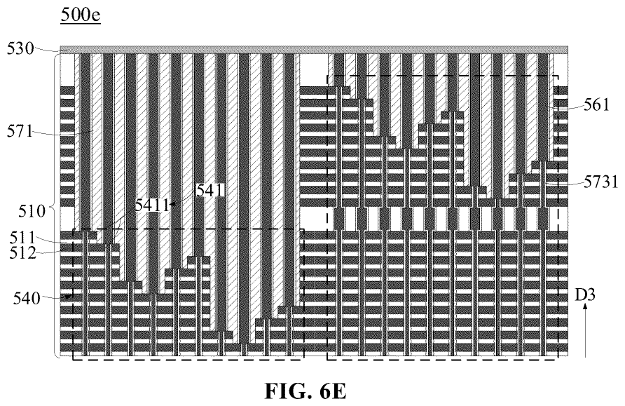

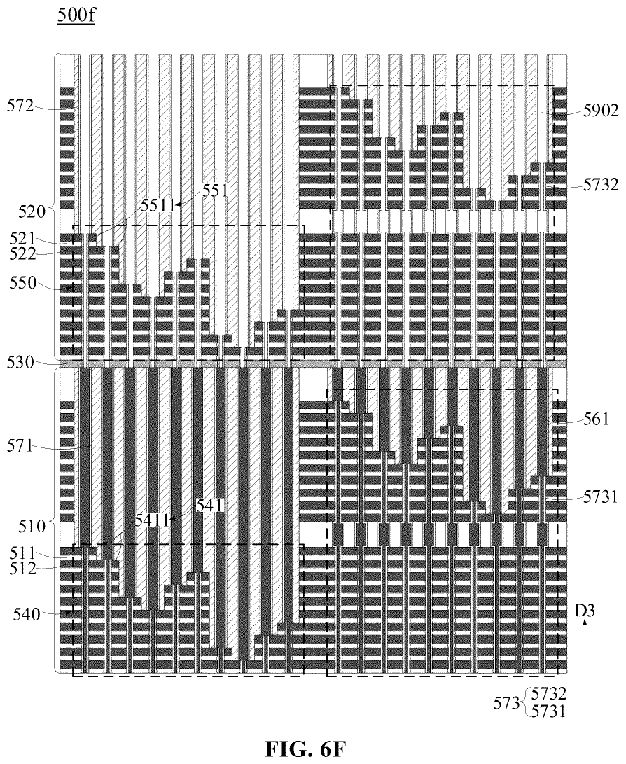

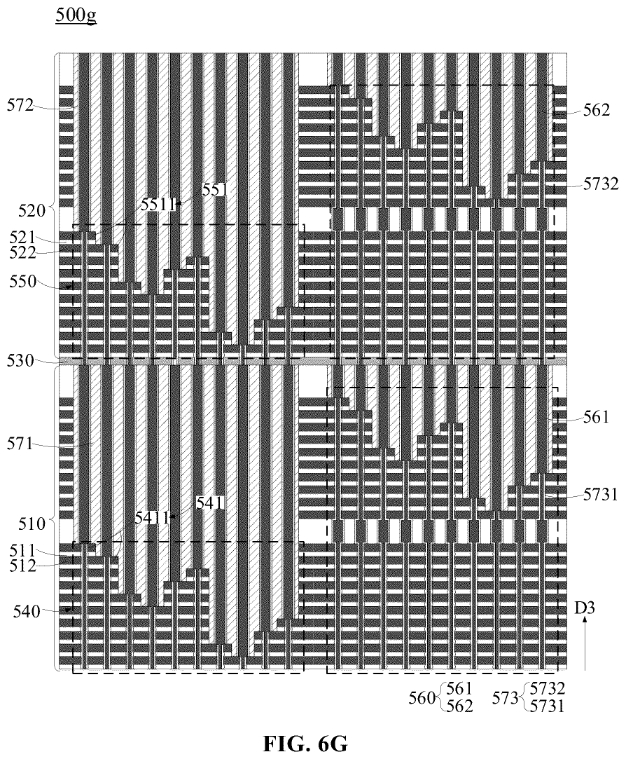

FIG. 6A to FIG. 6G are cross-sectional views of a semiconductor structure in a manufacturing process according to an example of the present disclosure. FIG. 6A illustrates an intermediate structure 500a after forming the initial first stack structure 510′ and the initial first staircase structure 540′. FIG. 6B illustrates an intermediate structure 500b after forming the first stack structure 510, the first staircase structure 540, and the first connection hole 5901. FIG. 6C shows an intermediate structure 500c after enlarging a portion of the first connection hole 5901. FIG. 6D illustrates an intermediate structure 500d after forming the first isolation portion 5731. FIG. 6E illustrates an intermediate structure 500e after forming the first connecting portion 561 and the semiconductor layer 530. FIG. 6F illustrates an intermediate structure 500f after forming the second stack structure 520, the second staircase structure 550, the second connection hole 5902, and the second isolation portion 5732. FIG. 6G illustrates an intermediate structure 500g after forming the second connecting portion 562.

The manufacturing method 400 comprising S410 to S440 is illustrated below with reference to FIGS. 6A to 6G.

In some implementations, as shown in FIG. 6A, the initial first stack structure 510′ may comprise a first dielectric layer 511 and a first sacrificial layer 515 that are formed alternately in the direction D3. For example, the first dielectric layer 511 and the first sacrificial layer 515 in the initial first stack structure 510′ may be located within the array region AR and the connection region CR shown in FIG. 1B. The materials of the first sacrificial layer 515 and the first dielectric layer 511 may be different. In a case where the material of the first dielectric layer 511 comprises silicon oxide, the material of the first sacrificial layer 515 may comprise silicon nitride. For example, the first dielectric layer 511 and the first sacrificial layer 515 may be formed by a thin film deposition process of chemical vapor deposition (CVD), physical vapor deposition (PVD), atomic layer deposition (ALD), or any combination thereof.

An initial first staircase structure 540′ may be formed in the initial first stack structure 510′. The initial first staircase structure 540′ may comprise a plurality of initial first step structures 541′ arranged along a circumferential direction. In an example, the initial first step structure 541′ may comprise a plurality of initial first step sub-structures 5411′ arranged along the radial direction. The initial first staircase structure 540′ may be formed by trimming/etching the initial first stack structure 510′. Thus, the initial first staircase structure 540′ may comprise the first dielectric layer 511 and the first sacrificial layer 515 disposed alternately in the direction D3. A top layer of each initial first step structure 541′ (or each initial first step sub-structure 5411′) is a first sacrificial layer 515. For example, the plurality of initial first staircase structures 540′ may be located within the connection region CR shown in FIG. 1B.

Further, as shown in FIG. 6B, the first sacrificial layer 515 may be replaced with the first gate layer 512, so that the initial first stack structure 510′ is converted into the first stack structure 510. For example, the first sacrificial layer 515 may be replaced with the first gate layer 512 by employing a trench (not shown) corresponding to the gate line isolation structure 180 shown in FIG. 1B. The initial first staircase structure 540′ is converted into a first staircase structure 540. The first staircase structure 540 may comprise a first dielectric layer 511 and a first gate layer 512 disposed alternately in the direction D3. A top layer of each of the first staircase structures 541 (or each of the first step sub-structures 5411) is a first gate layer 512.

In some implementations, as shown in FIGS. 6A and 6B, the first insulating structure 571 may be formed on a side of the first staircase structure 540 having a staircase surface by a thin film deposition process of CVD, PVD, ALD, or any combination thereof. In other words, the first insulating structure 571 may be formed on a side of the first staircase structure 540 close to the semiconductor layer 530 (referring to FIG. 6E) to be formed.

In some examples, as shown in FIG. 6B, an etching (e.g., dry etching and/or wet etching) process may be employed to form the first connection hole 5901 extending through the first insulating structure 571 and the first staircase structure 540. For example, the first connection hole 5901 may extend in the direction D3. From the direction D3, the first connection hole 5901 may be located in a region defined by one horizontal surface of one first step structure 541 (or the first step sub-structure 5411).

In some implementations, as shown in FIGS. 6B and 6C, an etching (e.g., wet etching) process may be employed to remove a portion of the first insulating structure 571 and the first dielectric layer 511 at periphery of the first connection hole 5901. In other words, a portion of the first connection hole 5901 extending through the first insulating structure 571 and the first dielectric layer 511 may be enlarged. After the above process, in a plane perpendicular to the direction D3, a dimension (e.g., a diameter) of a portion of the first connection hole 5901 extending through the first insulating structure 571 and a dimension (e.g., a diameter) of a portion of the first connection hole 5901 extending through the first dielectric layer 511 are greater than a dimension (e.g., a diameter) of a portion of the first connection hole 5901 extending through the first gate layer 512.

In some implementations, as shown in FIGS. 6C and 6D, the manufacturing method 400 may further comprise forming a first isolation portion 5731 on a sidewall of a portion of the first staircase structure 540 through which the first connection hole 5901 extends. As an example, an initial first isolation portion (not shown) may be formed on a sidewall of the first connection hole 5901 by a thin film deposition process of CVD, PVD, ALD, or any combination thereof. For example, the initial first isolation portion may cover a surface of the first gate layer 512 of the top layer in the first staircase structure 540.

Further, an etching (e.g., dry etching) process may be employed to remove a portion of the initial first isolation portion at the surface of the first gate layer 512 of the top layer in the first staircase structure 540. Thus, the first gate layer 512 of the top layer in the first staircase structure 540 is exposed. Since in the plane perpendicular to the direction D3, the dimension of the portion of the first connection hole 5901 extending through the first insulating portion 571 is greater than the dimension of the portion of the first connection hole 5901 extending through the first gate layer 512 in the first staircase structure 540, in the above etching process, the portion of the initial first isolation portion located on the sidewall of the portion of the first connection hole 5901 extending through the first staircase structure 540 is reserved, that is, the remaining unetched initial first isolation portion may be the first isolation portion 5731.

Further, as shown in FIGS. 6D and 6E, a conductive material is filled into the first connection hole 5901 formed with the first isolation portion 5731 to form the first connecting portion 561, by a thin film deposition process of CVD, PVD, ALD, or any combination thereof. The first connecting portion 561 may be connected (e.g., in contact) with the first gate layer 512 of the top layer in the first staircase structure 540, and electrically isolated from the first gate layer 512 of the non-top layer in the first staircase structure 540 through the first isolation portion 5731.

With continued reference to FIG. 6E, the semiconductor layer 530 may be formed on a side of the first stack structure 510 by a thin film deposition process of CVD, PVD, ALD, or any combination thereof. For example, the semiconductor layer 530 may be formed within the array region AR and the connection region CR shown in FIG. 1B. For another example, the semiconductor layer 530 may be formed within the array region AR shown in FIG. 1B and not within the connection region CR. In an example, the semiconductor layer 530 located at the connection region CR may be replaced by an insulating material layer (not shown).

As shown in FIG. 6F, a second stack structure 520 may be formed on a side of the semiconductor layer 530 away from the first stack structure 510, and a second staircase structure 550 may be formed in the second stack structure 520. The second staircase structure 550 may comprise a plurality of second staircase structures 551 arranged along a circumferential direction. In an example, the second staircase structure 551 may comprise a plurality of second step sub-structures 5511 arranged along the radial direction.

In some implementations, as described above, the second stack structure 520 and the second staircase structure 550 may be provided by replacing the second sacrificial layer in the initial second stack structure and the initial second staircase structure with the second gate layer 522. Thus, the second stack structure 520 and the second staircase structure 550 comprise the second dielectric layers 521 and the second gate layers 522 arranged alternately in the direction D3. In another implementation, the first sacrificial layer 515 (referring to FIG. 6A) and the second sacrificial layer may be replaced with the first gate layer 512 and the second gate layer 522 in the same process.

In some implementations, the second insulating structure 572 may be formed on a side of the second staircase structure 550 having a staircase surface by a thin film deposition process of CVD, PVD, ALD, or any combination thereof. In other words, the second insulating structure 572 may be formed on a side of the second staircase structure 550 away from the semiconductor layer 530.

In some implementations, an etching (e.g., dry etching and/or wet etching) process may be employed to form the second connection hole 5902 extending through the second insulating structure 572 and the second staircase structure 550. For example, the second connection hole 5902 may expose the first connecting portion 561. Further, a portion of the second insulating structure 572 and the second dielectric layer 521 at periphery of the second connection hole 5902 may be removed by an etching (e.g., wet etching) process. In other words, a portion of the second connection hole 5902 extending through the second insulating structure 572 and the second dielectric layer 521 may be enlarged. After the above process, in a plane perpendicular to the direction D3, a dimension (e.g., a diameter) of a portion of the second connection hole 5902 extending through the second insulating structure 572 and a dimension (e.g., a diameter) of a portion of the second connection hole 5902 extending through the second dielectric layer 521 are greater than a dimension (e.g., a diameter) of a portion of the second connection hole 5902 extending through the second gate layer 522.

In some implementations, the manufacturing method 400 may further comprise forming the second isolation portion 5732 on a sidewall of a portion of the second staircase structure 550 through which the second connection hole 5902 extends. As an example, an initial second isolation portion (not shown) may be formed on a sidewall of the second connection hole 5902 by a thin film deposition process of CVD, PVD, ALD, or any combination thereof. For example, the initial second isolation portion may cover a surface of the second gate layer 522 of the top layer in the second staircase structure 550. Further, an etching (e.g., dry etching) process may be employed to remove a portion of the initial second isolation portion at the surface of the second gate layer 522 of the top layer in the second staircase structure 550. Thus, the second gate layer 522 of the top layer in the second staircase structure 550 is exposed. Since in the plane perpendicular to the direction D3, the dimension of the portion of the second connection hole 5902 extending through the second insulating structure 572 is greater than the dimension of the portion of the second connection hole 5902 extending through the second gate layer 522 in the second staircase structure 550, in the above etching process, the portion of the initial second isolation portion located on the sidewall of the portion of the second connection hole 5902 extending through the second staircase structure 550 is reserved, that is, the remaining unetched initial second isolation portion may be the second isolation portion 5732. The first isolation portion 5731 and the second isolation portion 5732 may be referred to as an isolation layer 573. The isolation layer 573 may be formed on sidewalls of a portion of the first connection hole 5901 (refer to FIG. 6C) and the second connection hole 5902 extending through the first staircase structure 540 and the second staircase structure 550 respectively.

In some implementations, as shown in FIGS. 6F and 6G, a conductive material is filled into the second connection hole 5902 formed with the second isolation portion 5732 to form the second connecting portion 562, by a thin film deposition process of CVD, PVD, ALD or any combination thereof. The second connecting portion 562 may be connected (e.g., in contact) with the second gate layer 522 of the top layer in the second staircase structure 550, and electrically isolated from the second gate layer 522 of the non-top layer in the second staircase structure 550 through the second isolation portion 5732. The first connecting portion 561 and the second connecting portion 562 may be referred to as a connection structure 560.

In another implementation, after forming the first stack structure 510 and the second stack structure 520 (or the initial first stack structure 510′ (referring to FIG. 6A) and the initial second stack structure), the connection holes extending through the second insulating structure 572, the second staircase structure 550, the first insulating structure 571 and the first staircase structure 540 may be formed in the same process, and the isolation layer 573 may be formed on a sidewall of a portion of the first staircase structure 540 and the second staircase structure 550 through which the connection hole extends in the same process step, and then the connection structure 560 is formed in the connection hole in which the isolation layer 573 is formed. The specific sequence of forming the connection hole, the isolation layer 573 and the connection structure 560 is not limited in the present disclosure.

After the above process, the connection structure 560 may be connected with one first step structure 541 (or a first step sub-structure 5411) and one second staircase structure 551 (or a second step sub-structure 5511).

In some implementations, the manufacturing method 400 may further comprise: forming a first bit line structure on a side of the first stack structure 510 away from the semiconductor layer 530, and forming a second bit line structure on a side of the second stack structure away from the semiconductor layer 530. The first bit line structure and the second bit line structure extend in the direction D1.

In some implementations, the manufacturing method 400 may further comprise forming a first channel structure extending through the second stack structure 520, the semiconductor layer 530 and the first stack structure 510. The first channel structure is connected with the first bit line structure and the second bit line structure.

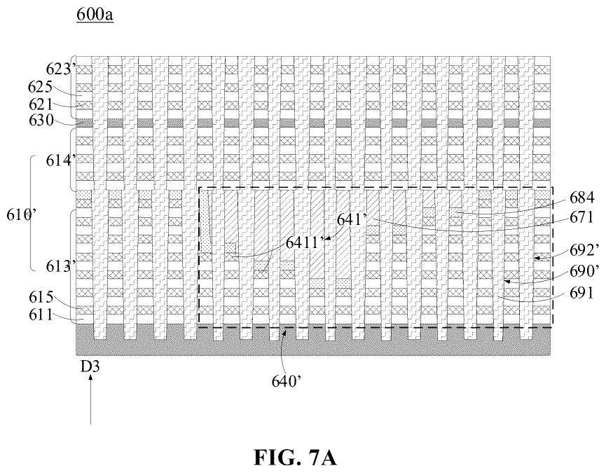

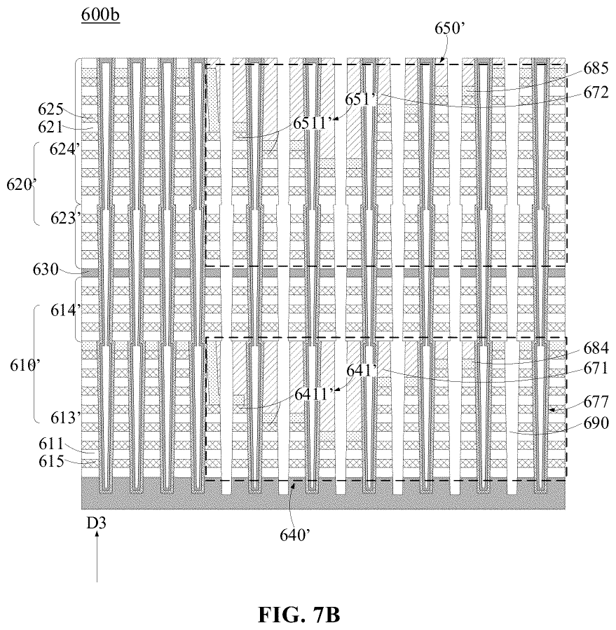

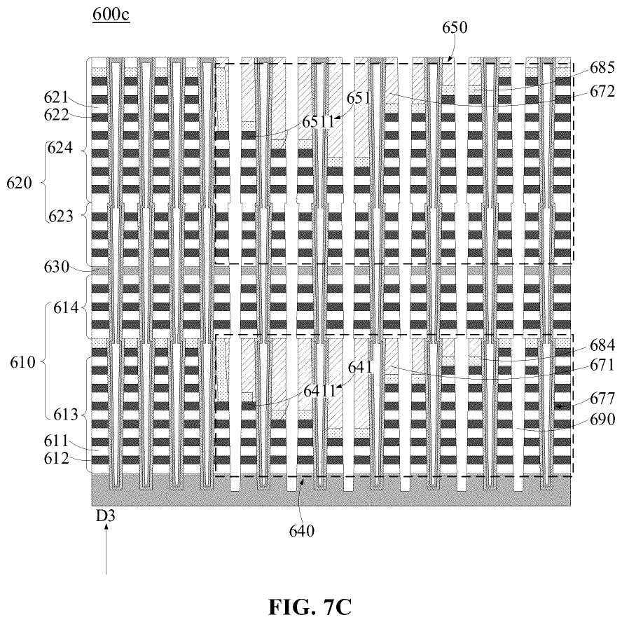

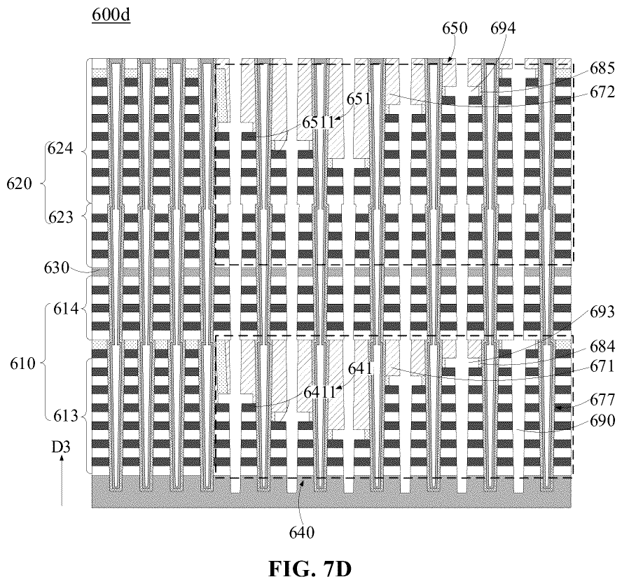

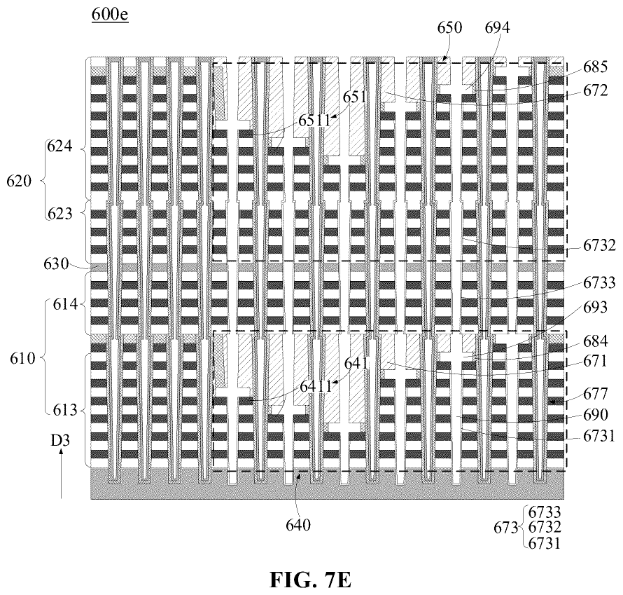

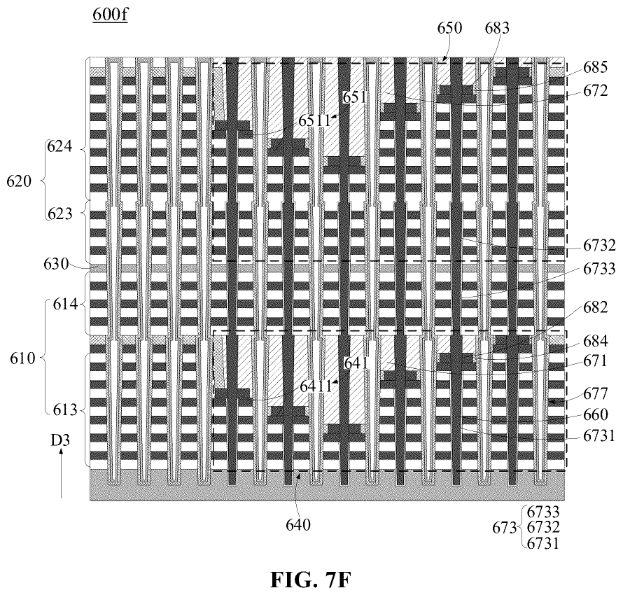

FIG. 7A to FIG. 7F are cross-sectional views of a semiconductor structure in a manufacturing process according to another example of the present disclosure. FIG. 7A illustrates an intermediate structure 600a after forming the initial first stack structure 610′ and the initial first staircase structure 640′ and the initial connection hole 690′. FIG. 7B illustrates an intermediate structure 700b after forming the semiconductor layer 630, the initial second stack structure 620′, the initial second staircase structure 650′, and the connection hole 690. FIG. 7C illustrates an intermediate structure 600c after forming the first stack structure 610, the first staircase structure 640, the second stack structure 620, and the second staircase structure 650. FIG. 7D shows an intermediate structure 600d after forming the first annular groove 693 and the second annular groove 694. FIG. 7E illustrates an intermediate structure 600e after forming the isolation layer 673. FIG. 7F illustrates an intermediate structure 600f after forming the connection structure 660.

The manufacturing method 400 comprising S410 to S440 is illustrated below with reference to FIGS. 7A to 7F. For ease of description, in this implementation, the same content as the previous example will not be described herein again.

In some implementations, as shown in FIG. 7A, an initial first stack portion 613′ may be formed first, and an initial first staircase structure 640′ may be formed in the initial first stack portion 613′. The initial first stack portion 613′ and the initial first staircase structure 640′ may each comprise a first dielectric layer 611 and a first sacrificial layer 615 disposed alternately in the direction D3. The initial first staircase structure 640′ may comprise a plurality of initial first step structures 641′ arranged along a circumferential direction. In an example, the initial first step structure 641′ may comprise a plurality of initial first step sub-structures 6411′ arranged along the radial direction. For example, a top layer of each of the initial first step structures 641′ (or each of the initial first step sub-structures 6411′) is a first sacrificial layer 615.

Next, a first insulating layer 684 covering the surface of the initial first staircase structure 640′ may be formed. Subsequently, a first insulating structure 671 may be formed on a side of the first insulating layer 684 away from the initial first staircase structure 640′. Thus, the first insulating layer 684 may be formed between the initial first staircase structure 640′ and the first insulating structure 671. For example, the first insulating layer 684 is in contact with the first sacrificial layer 615 of the top layer of each of the initial first step structures 641′ (or each of the initial first step sub-structures 6411′).

Further, an initial second stack portion 614′ covering the initial first stack portion 613′ and the first insulating structure 671 may be formed, and a semiconductor layer 630 and an initial third stack portion 623′ are formed sequentially on a side of the initial second stack portion 614′ away from the initial first stack portion 613′. The initial second stack portion 614′ may comprise a first dielectric layer 611 and a first sacrificial layer 615 disposed alternately in the direction D3. The initial first stack portion 613′ and the initial second stack portion 614′ may constitute the initial first stack structure 610′. The initial third stack portion 623′ may comprise second dielectric layers 621 and second sacrificial layers 625 arranged alternately in the direction D3. The initial third stack portion 623′ may be a portion of the initial second stack structure 620′ (see FIG. 7B).

It should be noted that the semiconductor layer 630 may be formed within the array region AR and the connection region CR shown in FIG. 1B. In another example, the semiconductor layer 630 may be formed within the array region AR shown in FIG. 1B and not within the connection region CR. In an example, the semiconductor layer 630 located at the connection region CR may be replaced by an insulating material layer (not shown).

In some implementations, an initial connection hole 690′ may be formed sequentially through the initial third stack portion 623′, the semiconductor layer 630 (or the insulating material layer), the initial second stack portion 614′, the first insulating structure 671, and the initial first staircase structure 640′. In an example, an initial second channel hole 692′ may be formed sequentially through the initial third stack portion 623′, the semiconductor layer 630 (or the insulating material layer), the initial second stack portion 614′, the first insulating structure 671, and the initial first staircase structure 640′. Subsequently, the sacrificial material 691 may be filled in the initial connection hole 690′ and the initial second channel hole 692′.

In other implementations, the initial connection hole 690′, the initial second channel hole 692′ and the sacrificial material 691 filled in both of them may be implemented by etching and filling in steps. For example, after forming the initial first stack portion 613′, the initial first staircase structure 640′ and the first insulating structure 671, a first etching and filling process is performed to form the initial connection hole 690′ and a portion of the sacrificial material 691 therein. Next, after forming the initial second stack portion 614′, the semiconductor layer 630 and the initial third stack portion 623′, a second etching and filling process is performed to form the complete initial connection hole 690′ and the sacrificial material 691 therein.

In some implementations, as shown in FIG. 7B, an initial fourth stack portion 624′ may be formed on a side of the initial third stack portion 623′ away from the semiconductor layer 630. The initial fourth stack portion 624′ may comprise the second dielectric layers 621 and the second sacrificial layers 625 formed alternately in the direction D3. The initial third stack portion 623′ and the initial fourth stack portion 624′ may constitute the initial second stack structure 620′.

In some implementations, an initial second staircase structure 650′ may be formed in the initial second stack structure 620′. The initial second staircase structure 650′ may comprise a plurality of initial second step structures 651′ arranged along a circumferential direction. In an example, the initial second step structure 651′ may comprise a plurality of initial second step sub-structures 6511′ arranged along the radial direction. For example, the top layer of each of the initial second step structures 651′ (or each of the initial second step sub-structures 6511′) is the second sacrificial layer 625.

Next, a second insulating layer 685 covering the surface of the initial second staircase structure 650′ may be formed. Subsequently, a second insulating structure 672 may be formed on a side of the second insulating layer 685 away from the initial second staircase structure 650′. Thus, the second insulating layer 685 may be formed between the initial second staircase structure 650′ and the second insulating structure 672. For example, the second insulating layer 685 is in contact with the second sacrificial layer 625 of the top layer of each of the initial second step structures 651′ (or each of the initial second step sub-structures 6511′).

In some implementations, a via extending sequentially through the second insulating structure 672 and the initial second staircase structure 650′ and, for example, exposing the sacrificial material 691 in the initial connection hole 690′, may be formed. The via and the initial connection hole 690′ may be referred to as a connection hole 690. Next, the sacrificial material 691 in the connection hole 690 may be removed.

In some implementations, another via extending sequentially through the second insulating structure 672 and the initial second staircase structure 650′ and, for example, exposing the sacrificial material 691 in the initial second channel hole 692′, may be formed. The via and the initial second channel hole 692′ may be referred to as a second channel hole (corresponding to an outer profile of the second channel structure 677). Next, the sacrificial material 691 in the second channel hole may be removed, and the second channel structure 677 may be formed in the second channel hole.

In some implementations, as shown in FIGS. 7B and 7C, the first sacrificial layer 615 may be replaced with the first gate layer 612, and the second sacrificial layer 625 may be replaced with the second gate layer 622. The initial first stack structure 610′, the initial first staircase structure 640′, the initial second stack structure 620′ and the initial second staircase structure 650′ are converted into the first stack structure 610, the first staircase structure 640, the second stack structure 620 and the second staircase structure 650 respectively. For example, the first insulating layer 684 may be in contact with the first gate layer 612 of the top layer of each of the first step structures 641 (or each of the first step sub-structures 6411). The second insulating layer 685 may be in contact with the second gate layer 622 of the top layer of each of the second step structures 651 (or each of the second step sub-structures 6511). The connection hole 690 may extend through the first insulating layer 684 and the second insulating layer 685. In the above-described replacement process, the second channel structure 677 may be configured to provide mechanical support.

In some implementations, as shown in FIG. 7D, a portion of the first insulating layer 684 at periphery of the connection hole 690 may be removed by an etching (e.g., wet etching) process to form the first annular groove 693, and a portion of the second insulating layer 685 at periphery of the connection hole 690 may be removed to form the second annular groove 694. The first annular groove 693, the second annular groove 694, and the contact hole 690 are connected. The first annular recess 693 may expose the first gate layer 612 of the top layer of each first step structure 641 (or each first step sub-structure 6411). The second annular recess 694 may expose the second gate layer 622 of the top layer of each of the second step structures 651 (or each of the second step sub-structures 6511).

In some implementations, as shown in FIGS. 7D and 7E, an initial isolation layer (not shown) may be formed on the connection hole 690 and the inner walls of the first annular groove 693 and the second annular groove 694 by a thin film deposition process of CVD, PVD, ALD, or any combination thereof. Subsequently, a portion of the initial isolation layer on the inner walls of the first annular groove 693 and the second annular groove 694 may be removed by an etching-back process. Since in the plane perpendicular to the direction D3, the dimension of the first annular groove 693 and the dimension of the second annular groove 694 are greater than the dimension of the portion of the connection hole 690 extending through the first staircase structure 640, the dimension of the portion of the connection hole 690 extending through the second staircase structure 650, and the dimension of the portion of the connection hole 690 extending through the second stack portion 614. In the above etching-back process, the portion of the initial isolation layer located on the sidewall of the portion of the connection hole 690 extending through the first staircase structure 640, the second staircase structure 650 and the second stack portion 614 is retained, that is, the remaining unetched initial isolation layer may be the isolation layer 673. The portion of the isolation layer 673 located on the sidewall of the portion of the connection hole 690 extending through the first staircase structure 640 may be the first isolation portion 6731, the portion of the isolation layer 673 located on the sidewall of the portion of the connection hole 690 extending through the second staircase structure 650 may be the second isolation portion 6732, and the portion of the isolation layer 673 located on the sidewall of the portion of the connection hole 690 extending through the second stack portion 614 may be the third isolation portion 6733.

In some implementations, as shown in FIGS. 7E and 7F, the conductive material may be filled in the connection hole 690, the first annular groove 693, and the second annular groove 694 by a thin film deposition process of CVD, PVD, ALD, or any combination thereof. A portion of the conductive material filled in the connection hole 690 may be a connection structure 660, a portion of the conductive material filled in the first annular groove 693 may be a first surrounding portion 682, and a portion of the conductive material filled in the second annular groove 694 may be a second surrounding portion 683. For example, the connection structure 660, the first surrounding portion 682, and the second surrounding portion 683 may be an integral structure.

After the above processing, the connection structure 660 may be connected with one first step structure 641 (or the first step sub-structure 6411) through the first surrounding portion 682, and connected with one second step structure 651 (or the second step sub-structure 6511) through the second surrounding portion 683. For example, the first surrounding portion 682 may be in contact with the first gate layer 612 of the top layer in one first step structure 641 (or the first step sub-structure 6411), and the second surrounding portion 683 may be in contact with the second gate layer 622 of the top layer in one second step structure 651 (or the second step sub-structure 6511).

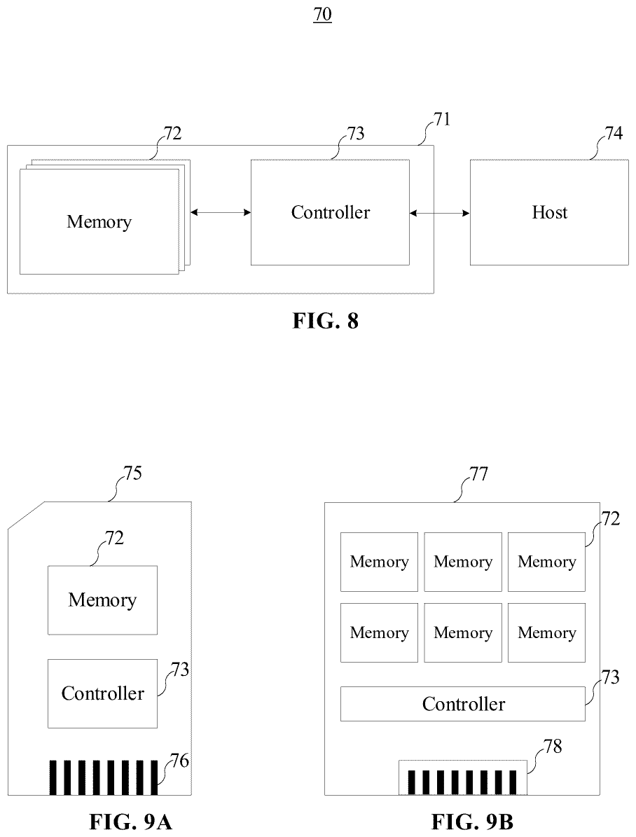

An example of this disclosure further provides a memory system. FIG. 8 is a schematic block diagram of a system with a memory system according to an example of this disclosure. FIG. 9A and FIG. 9B are schematic block diagrams of a memory system according to an example of this disclosure.

As shown in FIG. 8, the system 70 may be a mobile phone, a desktop computer, a laptop, a tablet, a vehicle computer, a game console, a printer, a positioning device, a wearable electronic device, a smart sensor, a virtual reality (VR) device, an augmented reality (AR) device, or any other suitable electronic device having a memory system 71 therein. As shown in FIG. 8, the system 70 may comprise a host 74 and a memory system 71 having one or more memories 72 and a controller 73. The host 74 may be a processor of an electronic device, such as a central processing unit (CPU), or may be a system-on-chip (SoC), such as an application processor (AP). The host 74 may be configured to transmit or receive data to and from the memory 72.

The memory 72 may comprise the semiconductor structure described in any implementation of the present disclosure, for example, the semiconductor structure 100 shown in FIG. 1A to FIG. 1F, the semiconductor structure 200 shown in FIG. 3, and the semiconductor structure 300 shown in FIG. 4. According to some implementations, the controller 73 is coupled to the memory 72 and the host 74 and is configured to control the memory 72. The controller 73 may manage data stored in the memory 72 and communicate with the host 74. In some implementations, the controller 73 is designed to operate in a low duty cycle environment, such as a secure digital (SD) card, compact flash (CF) card, universal serial bus (USB) flash drive, or other medium used in electronic devices such as personal computers, digital cameras, mobile phones, and the like. In some implementations, the controller 73 is designed to operate in a high duty cycle environment, such as an SSD or embedded multi-media-card (eMMC) functioning as a data storage device of a mobile device (such as a smartphone, a tablet, a laptop, or the like), and an enterprise storage array. The controller 73 may be configured to control operations of the memory 72, such as read, erase, and program operations. The controller 73 may also be configured to manage various functions related to data stored in the memory 72 or to be stored in the memory 72 including, but not limited to, bad block management, garbage collection, logical-to-physical address translation, wear leveling, and the like. In some implementations, the controller 73 is further configured to process error correction code (ECC) related to data read from or written to the memory 72. Other suitable functions may also be performed by the controller 73, such as formatting the memory 72. The controller 73 may communicate with an external device (e.g., host 74) according to a particular communication protocol. For example, the controller 73 may communicate with external devices through at least one of a variety of interface protocols, such as a USB protocol, an MMC protocol, a Peripheral Component Interconnect (PCI) protocol, a PCI-express (PCI-E) protocol, an Advanced Technology Attachment (ATA) protocol, a Serial ATA protocol, a parallel ATA protocol, a Small Computer Small Interface (SCSI) protocol, an Enhanced Small Disk Interface (ESDI) protocol, an Integrated Drive Electronics (IDE) protocol, a Firewire protocol, or the like.

The controller 73 and the one or more memories 72 may be integrated into various types of memory systems, e.g., comprised in the same package, such as a Universal Flash Storage (UFS) package or an eMMC package. That is, the memory system 71 may be implemented and packaged into different types of final electronic products. In one example as shown in FIG. 9A, the controller 73 and the single memory 72 may be integrated into the memory card 75. The memory card 75 may comprise a PC Card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), UFS, or the like. The memory card 75 may further comprise a memory card connector 76 that couples the memory card 75 to a host (for example, the host 74 in FIG. 8). In another example as shown in FIG. 9B, the controller 73 and a plurality of memories 72 may be integrated into an SSD 77. The SSD 77 may further comprise an SSD connector 78 that couples the SSD 77 to a host (for example, the host 74 in FIG. 8). In some implementations, the storage capacity and/or operating speed of SSD 77 is higher than that of the memory card 75.

The above description is merely the implementation and description of principles of the present disclosure. It should be understood by those skilled in the art that the protection scope involved in this disclosure is not limited to the technical solutions of the specific combination of the technical features described above, and should also encompass other technical solutions formed by any combination of the foregoing technical features or their equivalent features without departing from the technical concept, for example, the technical solutions formed by replacing the aforementioned technical features with technical features having similar functions (but not limited thereto) disclosed in the present disclosure.

What is claimed is:

1. A semiconductor structure, comprising:
a first stack structure;
a second stack structure on a side of the first stack structure;
a semiconductor layer between the first stack structure and the second stack structure;
a first staircase structure located in the first stack structure, the first staircase structure comprising a plurality of first step structures arranged along a first circumferential direction;
a second staircase structure located in the second stack structure, the second staircase structure comprising a plurality of second step structures arranged along a second circumferential direction; and
a connection structure extending along a stacking direction of the first stack structure and the second stack structure, the connection structure being connected with a first step structure of the plurality of first step structures and a second step structure of the plurality of second step structures.

2. The semiconductor structure of claim 1, wherein the first step structure comprises a plurality of first step sub-structures arranged along a first radial direction, and the second step structure comprises a plurality of second step sub-structures arranged along a second radial direction, and
wherein the connection structure is connected with one of the first step sub-structures and one of the second step sub-structures.

3. The semiconductor structure of claim 2, wherein, with respect to the semiconductor layer, depths of the plurality of first step sub-structures are different from each other, and depths of the plurality of second step sub-structures are different from each other.

4. The semiconductor structure of claim 1, wherein, in a plane perpendicular to the stacking direction, the first staircase structure comprises a plurality of first step regions arranged along the first circumferential direction, the first step structure is located in adjacent first step regions, the second staircase structure comprises a plurality of second step regions arranged along the second circumferential direction, and the second step structure is located in adjacent second step regions, and
wherein a shape of the first step region comprises a first sector, and a shape of the second step region comprises a second sector.

5. The semiconductor structure of claim 1, wherein the first staircase structure and the second staircase structure are at least partially aligned in the stacking direction.

6. The semiconductor structure of claim 1, further comprising:
a first insulating structure on a first side of the first staircase structure close to the semiconductor layer; and
a second insulating structure on a second side of the second staircase structure away from the semiconductor layer,
wherein the connection structure extends through the second insulating structure, the second staircase structure, the first insulating structure, and the first staircase structure.

7. The semiconductor structure of claim 6, further comprising:
an isolation layer surrounding a portion of the connection structure extending through the first staircase structure and the second staircase structure.

8. The semiconductor structure of claim 6, wherein:
in a first plane perpendicular to the stacking direction, a dimension of a portion of the connection structure extending through the first insulating structure is greater than a dimension of a portion of the connection structure extending through the first staircase structure, and
in a second plane perpendicular to the stacking direction, a dimension of a portion of the connection structure extending through the second insulating structure is greater than a dimension of a portion of the connection structure extending through the second staircase structure.

9. The semiconductor structure of claim 7, further comprising:
a first surrounding portion surrounding the connection structure and contacting the first staircase structure; and
a second surrounding portion surrounding the connection structure and contacting the second staircase structure.

10. The semiconductor structure of claim 9, wherein the first stack structure comprises a first stack portion and a second stack portion arranged along the stacking direction, the first staircase structure is located in the first stack portion, the second stack portion covers the first insulating structure, the connection structure extends through the second stack portion, and the isolation layer surrounds a portion of the connection structure extending through the second stack portion.

11. The semiconductor structure of claim 9, further comprising:
a first insulating layer between the first staircase structure and the first insulating structure; and
a second insulating layer between the second staircase structure and the second insulating structure.

12. The semiconductor structure of claim 6, wherein the connection structure comprises a plurality of connection sub-structures arranged along the stacking direction, and
wherein a connection sub-structure of the plurality of connection sub-structures has a dimension in a plane perpendicular to the stacking direction, and dimensions of connection sub-structures of the plurality of connection sub-structures in corresponding planes perpendicular to the stacking direction increase gradually along the stacking direction.

13. The semiconductor structure of claim 1, further comprising:
a first bit line structure on a side of the first stack structure away from the semiconductor layer, the first bit line structure extending along a first direction; and
a second bit line structure on a side of the second stack structure away from the semiconductor layer, the second bit line structure extending along the first direction,
wherein the first direction intersects with the stacking direction.

14. The semiconductor structure of claim 13, further comprising:
a channel structure extending through the second stack structure, the semiconductor layer, and the first stack structure, the channel structure being connected with the first bit line structure and the second bit line structure.

15. The semiconductor structure of claim 1, further comprising:
a channel structure extending through the second staircase structure and the first staircase structure.

16. A memory system, comprising:
a memory comprising:
a semiconductor structure comprising:
a first stack structure;
a second stack structure on a side of the first stack structure;
a semiconductor layer between the first stack structure and the second stack structure;
a first staircase structure located in the first stack structure, the first staircase structure comprising a plurality of first step structures arranged along a first circumferential direction;
a second staircase structure located in the second stack structure, the second staircase structure comprising a plurality of second step structures arranged along a second circumferential direction; and
a connection structure extending along a stacking direction of the first stack structure and the second stack structure, the connection structure being connected with one of the plurality of first step structures and one of the plurality of second step structures; and
a controller coupled with the memory and configured to control the memory.

17. A manufacturing method of a semiconductor structure, comprising:
forming a first staircase structure in a first stack structure, wherein the first staircase structure comprises a plurality of first step structures arranged along a first circumferential direction;
forming a semiconductor layer on a side of the first stack structure;
forming a second stack structure on a side of the semiconductor layer away from the first stack structure, and forming a second staircase structure in the second stack structure, wherein the second staircase structure comprises a plurality of second step structures arranged along a second circumferential direction; and
forming a connection structure extending along a stacking direction of the first stack structure and the second stack structure, wherein the connection structure is connected with one of the first step structures and one of the second step structures.

18. The manufacturing method of claim 17, further comprising:
forming a first insulating structure on a side of the first staircase structure close to the semiconductor layer; and
forming a second insulating structure on a side of the second staircase structure away from the semiconductor layer.

19. The manufacturing method of claim 18, wherein forming the connection structure extending along the stacking direction of the first stack structure and the second stack structure comprises:
forming a connection hole extending through the second insulating structure, the second staircase structure, the first insulating structure, and the first staircase structure;
forming an isolation layer on a sidewall of a portion of the first staircase structure and the second staircase structure through which the connection hole extends; and
forming the connection structure in the connection hole where the isolation layer is formed.

20. The manufacturing method of claim 19, wherein:
the first staircase structure comprises first dielectric layers and first gate layers arranged alternately in the stacking direction, and
the second staircase structure comprises second dielectric layers and second gate layers arranged alternately in the stacking direction.
